(19) United States
(12) Patent Application Publication
(10) Pub. No.: US 2026/0302146 A1
(43) Pub. Date: Oct. 1, 2026

(54) Precise Feedback Control of Bias Voltage Tailored Waveform for Plasma Etch Processes

(71) Applicant: Lam Research Corporation, Fremont, CA (US)

(72) Inventors: Myeong Yeol Choi, Campbell, CA (US); Ying Wu, Livermore, CA (US); Alexander Miller Paterson, San Jose, CA (US)

(21) Appl. No.: 18/880,460

(22) PCT Filed: Jul. 10, 2023
(86) PCT No.: PCT/US2023/027295

§ 371 Date: Dec. 31, 2024

Related U.S. Application Data
(60) Provisional application No. 63/391,298, filed on Jul. 21, 2022.

(51) Int. Cl. H01J 37/32

(52) U.S. Cl. CPC H01J 37/3299; H01J 37/32146; H01J 37/32568; H01J 37/32642; H01J 2237/334

(57) ABSTRACT

A bias electrode and a mid-level electrode are disposed within a substrate support. A lower portion of the substrate support exists between the bias electrode and the mid-level electrode. An upper portion of the substrate support exists between the mid-level electrode and a top surface of the substrate support. A voltage supply system supplies a bias voltage tailored radiofrequency waveform to the bias electrode. A voltage measurement system measures a first voltage on the bias electrode and a second voltage on the mid-level electrode. A controller uses the first voltage, the second voltage, a capacitance of the substrate support lower portion, and a capacitance of the substrate support upper portion to determine a voltage on a top surface of a substrate present on the top surface of the substrate support. The controller conveys the voltage on the top surface of the substrate to the voltage supply system.

### BACKGROUND

Plasma processing systems are used to manufacture semiconductor devices, e.g., chips/die, on semiconductor wafers. In the plasma processing system, the semiconductor wafer is exposed to various types of plasma to cause prescribed changes to a condition of the semiconductor wafer, such as through material deposition and/or material removal and/or material implantation and/or material modification, etc. During plasma processing of the semiconductor wafer, radiofrequency (RF) power is transmitted through a process gas within a chamber to transform the process gas into the plasma in exposure to the semiconductor wafer. Reactive constituents of the plasma, such as radicals and ions, interact with materials on the semiconductor wafer to achieve a prescribed effect on the semiconductor wafer. In some plasma processing systems, bias voltage is applied at a level of the semiconductor wafer to attract charged constituents within the plasma toward the semiconductor wafer.

As the semiconductor industry continues to move toward reduced chip size and improved chip performance, it is necessary to use more high-density and high-aspect ratio features to define transistors on the chip, which leads to transistors being more sensitive to fabrication process variations. With shrinking on-chip feature sizes, some fabrication process variations of just a few atoms may necessitate improvement in etch uniformity control. Uniformity in ion flux, ion energy, and ion angular distribution across the semiconductor wafer is a demanding requirement for plasma etching and deposition for microelectronics fabrication. Also, achievement of substantially uniform ion flux, ion energy, and ion angular distribution at the edge of the semiconductor wafer is a meaningful challenge because approximately 10% of the die on the substrate are impacted by fabrication process results that occur within a radial distance of about 5 mm from the outer peripheral edge of the semiconductor wafer. It is within this context that various embodiments described herein arise.

### SUMMARY

In an example embodiment, a system includes a bias electrode disposed within a substrate support. The substrate support has a top surface configured to support a substrate. The system also includes a mid-level electrode disposed within the substrate support, such that a lower portion of the substrate support is present between the bias electrode and the mid-level electrode, and such that an upper portion of the substrate support is present between the mid-level electrode and the top surface of the substrate support. The system also includes a voltage supply system connected to supply a bias voltage tailored radiofrequency waveform to the bias electrode. The system also includes a voltage measurement system connected to measure a first voltage on the bias electrode and a second voltage on the mid-level electrode. The system also includes a controller configured to use the measured first voltage, the measured second voltage, a capacitance of the lower portion of the substrate support, and a capacitance of the upper portion of the substrate support to determine a voltage on a top surface of the substrate when present on the top surface of the substrate support. The controller is configured to convey information related to the voltage on the top surface of the substrate to the voltage supply system.

In an example embodiment, a substrate support system for a plasma processing system is disclosed. The substrate support system includes a substrate support that has a top surface configured to support a substrate. The substrate support system also includes a bias electrode disposed within the substrate support. The bias electrode is configured to control a voltage on a top surface of the substrate. The bias electrode is connected to receive a bias voltage tailored radiofrequency waveform from a voltage supply system. The bias electrode is configured to electrically receive a first connector for measuring a first voltage on the bias electrode. The substrate support system also includes a mid-level electrode disposed within the substrate support, such that a lower portion of the substrate support is present between the bias electrode and the mid-level electrode, and such that an upper portion of the substrate support is present between the mid-level electrode and the top surface of the substrate support. The mid-level electrode is configured to electrically receive a second connector for measuring a second voltage on the mid-level electrode.

In an example embodiment, an edge ring system for a plasma processing system is disclosed. The edge ring system includes an edge ring configured to circumscribe a substrate support. The edge ring system also includes an edge ring electrode disposed within the edge ring. The edge ring electrode is configured to control a voltage on a top surface of the edge ring. The edge ring electrode is connected to receive a bias voltage tailored radiofrequency waveform from a voltage supply system. The edge ring electrode is configured to electrically receive a first connector for measuring a first voltage on the edge ring electrode. The edge ring system also includes an edge ring mid-level electrode disposed within the edge ring, such that a lower portion of the edge ring is present between the edge ring electrode and the edge ring mid-level electrode, and such that an upper portion of the edge ring is present between the edge ring mid-level electrode and the top surface of the edge ring. The edge ring mid-level electrode is configured to electrically receive a second connector for measuring a second voltage on the edge ring mid-level electrode.

In an example embodiment, a method is disclosed for controlling voltage on a substrate. The method includes operating a voltage supply system to supply a bias voltage tailored radiofrequency waveform to a bias electrode within a substrate support. The method also includes measuring a first voltage on the bias electrode at a given time. The method also includes measuring a second voltage on a mid-level electrode at the given time. The mid-level electrode is disposed within the substrate support, such that a lower portion of the substrate support is present between the bias electrode and the mid-level electrode, and such that an upper portion of the substrate support is present between the mid-level electrode and the top surface of the substrate support. The method also includes using the measured first voltage, the measured second voltage, a capacitance of the lower portion of the substrate support, and a capacitance of the upper portion of the substrate support to determine a voltage on a top surface of a substrate when present on a top surface of the substrate support at the given time.

Other aspects and advantages of the embodiments disclosed herein will become more apparent from the following detailed description and the accompanying drawings.

### BRIEF DESCRIPTION OF THE DRAWINGS

FIG. 1A shows a vertical cross-section view through a plasma processing system, in accordance with some embodiments.

FIG. 1B shows a top view of the substrate disposed on the substrate support, referenced as View A-A in FIG. 1A, in accordance with some embodiments.

FIG. 2 shows voltages on the top surface of the substrate in response to supply of a constant amplitude RF voltage to the bias electrode by the bias RF generator, with two different ion flux conditions present at the top surface of the substrate, in accordance with some embodiments.

FIG. 3A shows a vertical cross-section view through a plasma processing system, in accordance with some embodiments.

FIG. 3B shows a top view of the substrate disposed on the substrate support, with the edge ring surrounding the substrate support, referenced as View A-A in FIG. 3A, in accordance with some embodiments.

FIG. 3C shows a top view of the mid-level electrode within the substrate support and the edge ring mid-level electrode within the edge ring, referenced as View B-B in FIG. 3A, in accordance with some embodiments.

FIG. 3D shows a bias voltage supply system that is an example implementation of the bias voltage supply system of FIG. 3A, in accordance with some embodiments.

FIG. 3E shows an example implementation of the voltage supply system within the bias voltage supply system of FIG. 3D, in accordance with some embodiments.

FIG. 3F shows an example bias voltage tailored waveform generated by the voltage supply system of FIG. 3E, and a corresponding bias voltage waveform on the top surface of the substrate, and a corresponding bias voltage waveform on the top surface of the edge ring, in accordance with some embodiments.

FIG. 3G shows a bias voltage supply system that is an example implementation of the bias voltage supply system of FIG. 3A, in accordance with some embodiments.

FIG. 4 shows an example diagram of the controller, in accordance with some embodiments.

FIG. 5 shows an example of a bias voltage tailored waveform supplied to the bias electrode by the bias voltage supply system of FIG. 3A and a corresponding voltage waveform that results on the top surface of the substrate, in accordance with some embodiments.

FIG. 6 shows a voltage waveform on the mid-level electrode within the substrate support that corresponds to the bias voltage tailored waveform supplied to the bias electrode by the bias voltage supply system as shown in FIG. 5, in accordance with some embodiments.

FIG. 7 shows an example of a bias voltage tailored waveform supplied to the bias electrode by the bias voltage supply system of FIG. 3A and a corresponding voltage waveform generated on the top surface of the substrate, in accordance with some embodiments.

FIG. 8 shows a feedback-controlled bias voltage tailored waveform supplied to the bias electrode by the bias voltage supply system of FIG. 3A and a corresponding voltage waveform generated on the top surface of the substrate, in accordance with some embodiments.

FIG. 9 shows another feedback-controlled bias voltage tailored waveform supplied to the bias electrode by the bias voltage supply system of FIG. 3A and a corresponding voltage waveform generated on the top surface of the substrate, in accordance with some embodiments.

FIG. 10A shows a flowchart of a method for controlling voltage on the substrate, in accordance with some embodiments.

FIG. 10B shows a flowchart of an optional continuation of the method of FIG. 10A for controlling voltage on the substrate, in accordance with some embodiments.

FIG. 10C shows a flowchart of an optional continuation of the method of either FIG. 10A or FIG. 10B, in accordance with some embodiments.

FIG. 10D shows a flowchart of an optional continuation of the method of FIG. 10C for controlling voltage on the edge ring, in accordance with some embodiments.

### DETAILED DESCRIPTION

In the following description, numerous specific details are set forth in order to provide a thorough understanding of the present disclosure. It will be apparent, however, to one skilled in the art that embodiments of the present disclosure may be practiced without some or all of these specific details. In other instances, well known process operations have not been described in detail in order not to unnecessarily obscure the present disclosure.

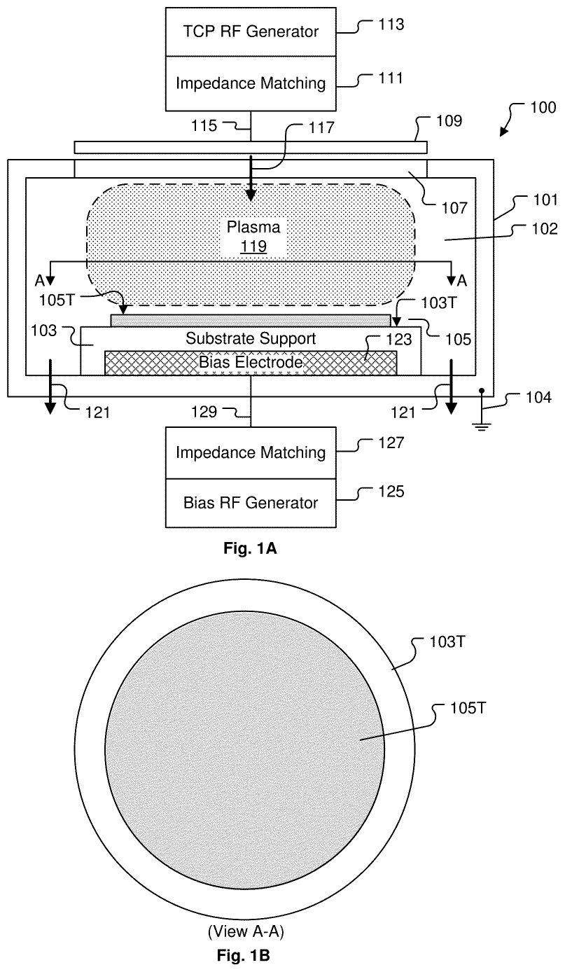

FIG. 1A shows a vertical cross-section view through a plasma processing system 100, in accordance with some embodiments. The plasma processing system 100 includes a chamber 101. A coil 109 is disposed above a window 107 of the chamber 101. In various embodiments, the window 107 is formed of a dielectric material, such as quartz or other similar material, that allows RF power to be transmitted from the coil 109 through the window 107 and into a plasma processing region 102 within the chamber 101. The chamber 101 is electrically connected to a reference ground potential 104. The plasma processing system 100 includes a TCP (transformer coupled plasma) RF generator 113 connected to deliver RF power through an impedance matching network 111 to the coil 109, as indicated by connection 115.

The plasma processing system 100 is also equipped to provide a controlled flow of a process gas or process gas mixture into the plasma processing region 102, as indicated by arrow 117. As the RF power is transmitted into and through the plasma processing region 102, the RF power transforms the process gas/mixture into a plasma 119 within the plasma processing region 102 in exposure to a substrate 105 that is supported on a substrate support 103 within the chamber 101. The substrate support 103 has a top surface 103T configured to support the substrate 105 during processing of the top surface 105T of the substrate 105 by the plasma 119 generated above the substrate support 103. In some embodiments, the substrate support 103 is an electrostatic chuck configured to generate an electrostatic force that holds the substrate 105 to the top surface 103T of the substrate support 103.

In various embodiments, the plasma 119 is generated to cause a change to the substrate 105 in a controlled manner. In various fabrication processes, the change to the substrate 105 can be a change in material or surface condition on the substrate 105. For example, in various fabrication processes, the change to the substrate 105 can include one or more of etching of a material from the substrate 105, deposition of a material on the substrate 105, implantation of a material into the substrate 105, and/or modification of material present on the substrate 105. Also, in some embodiments, the plasma 119 is generated in the plasma processing region 102 without the substrate 105 present to provide for cleaning of the chamber 101. It should be understood that the plasma processing system 100 can be any type of plasma processing system in which RF power is transmitted to the process gas/mixture within the plasma processing region 102 to generate the plasma 119 over the substrate 105 supported on the top surface 103T of the substrate support 103. The plasma processing system 100 is also equipped to provide for removal of gases and processing byproduct materials from the plasma processing region 102 through an exhaust system, as indicated by arrows 121.

FIG. 1B shows a top view of the substrate 105 disposed on the substrate support 103, referenced as View A-A in FIG. 1A, in accordance with some embodiments. In some embodiments, the substrate 105 is a semiconductor wafer undergoing a fabrication procedure. However, it should be understood that in various embodiments, the substrate 105 can be essentially any type of substrate that is subjected to a plasma-based fabrication process. For example, in some embodiments, the substrate 105 is formed of silicon, sapphire, GaN, GaAs or SiC, and/or other substrate materials, and can include glass panels/substrates, metal foils, metal sheets, polymer materials, or the like. Also, in various embodiments, the substrate 105 may vary in form, shape, and/or size. For example, in some embodiments, the substrate 105 is a semiconductor wafer with an outer diameter of 200 mm, 300 mm, 450 mm, or another size. Also, in some embodiments, the substrate 105 is a non-circular substrate, such as a rectangular substrate for a flat panel display, or the like, among other shapes.

As shown in FIG. 1A, in some embodiments, a bias electrode 123 is disposed within the substrate support 103 below the top surface 103T of the substrate support 103. In some embodiments, the substrate support 103 is formed of a dielectric material, such as a ceramic material or other type of dielectric material, with the bias electrode 123 formed of an electrically conductive material. In some embodiments, the plasma processing system 100 includes a bias RF generator 125 connected to deliver bias RF power through an impedance matching network 127 to the bias electrode 123, as indicated by connection 129. The bias electrode 123 is configured to apply a bias voltage to a top surface 105T of the substrate 105 to attract or repel electrically charged constituents of the plasma 119 toward or away from the substrate 105.

It should be understood that in various embodiments operation of the plasma processing system 100 can include many other additional operations, such as controlling a temperature of the substrate 105, and/or applying additional RF power to one or more electrode(s) disposed within the substrate support 103 to generate additional plasma, among other additional operations. Also, in various embodiments, the plasma processing system 100 is operated in accordance with a prescribed recipe that specifies a temporal schedule for controlling one or more of: supply of process gas(es) to the plasma processing region 102, pressure and temperature within the plasma processing region 102, supply of RF power to the coil 109, supply of bias RF power to the bias electrode 123, among essentially any other process parameter associated with operation of the plasma processing system 100.

The bias RF generator 125 is used to bias processing of the substrate 105 with a sinusoidal waveform voltage. When an RF signal is supplied to the bias electrode 123, the voltage on the top surface 105T of the substrate 105 periodically oscillates at the frequency of the RF signal. This technique for supplying RF bias voltage to the substrate 105 results in an uncontrolled distribution of bombarding ion energy for etching of features on the top surface 105T of the substrate 105. In some embodiments, because the bias RF generator 125 has a one-dimensional control knob of RF voltage amplitude, the bias RF generator 125 is not able to independently control the ion flux that is incident upon the substrate 105. In these embodiments, the ion flux incident upon the substrate 105 is determined by the RF power supplied by the TCP RF generator 113 to the coil 109 and by the amplitude of the RF bias voltage on the top surface 105T of the substrate 105, which directly impacts the energy of the ions incident upon the top surface 105T of the substrate 105. In some embodiments, the bias RF generator 125 is capable of regulating output RF power in either a power regulation mode or a voltage regulation mode.

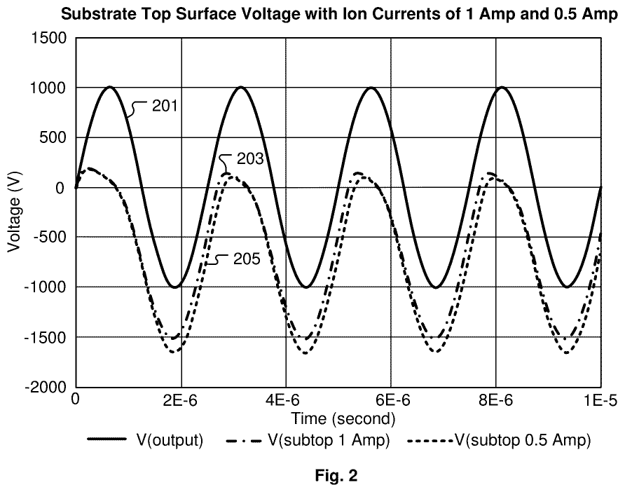

FIG. 2 shows voltages on the top surface 105T of the substrate 105 in response to supply of a constant amplitude RF voltage to the bias electrode 123 by the bias RF generator 125, with two different ion flux conditions present at the top surface 105T of the substrate 105, in accordance with some embodiments. The curve V(output) 201 represents the constant amplitude RF voltage supplied by the bias RF generator 125 to the bias electrode 123. The curve V(subtop 1 Amp) 203 represents the voltage on the top surface 105T of the substrate 105 in response the supplied RF bias voltage V(output) 201, with a 1 Amp ion current present on the top surface 105T of the substrate 105. The curve V(subtop 0.5 Amp) 205 represents the voltage on the top surface 105T of the substrate 105 in response the supplied RF bias voltage V(output) 201, with a 0.5 Amp ion current present on the top surface 105T of the substrate 105. FIG. 2 demonstrates that even with constant amplitude RF bias voltage supplied to the bias electrode 123 by the bias RF generator 125, the voltage on the top surface 105T of the substrate 105 can vary with the density of the plasma 119 and with the ion flux incident upon the substrate 105. Additionally, plasma-induced variations in the voltage behavior on the top surface 105T of the substrate 105 creates challenges with regard to transfer of substrate 105 fabrication recipes from one processing chamber to another processing chamber, as well as with modification of substrate 105 fabrication recipes.

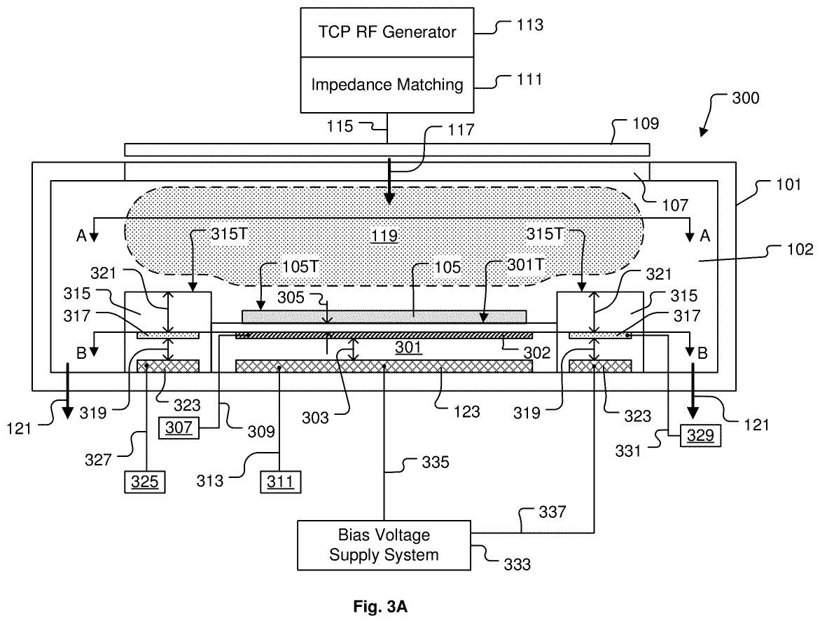

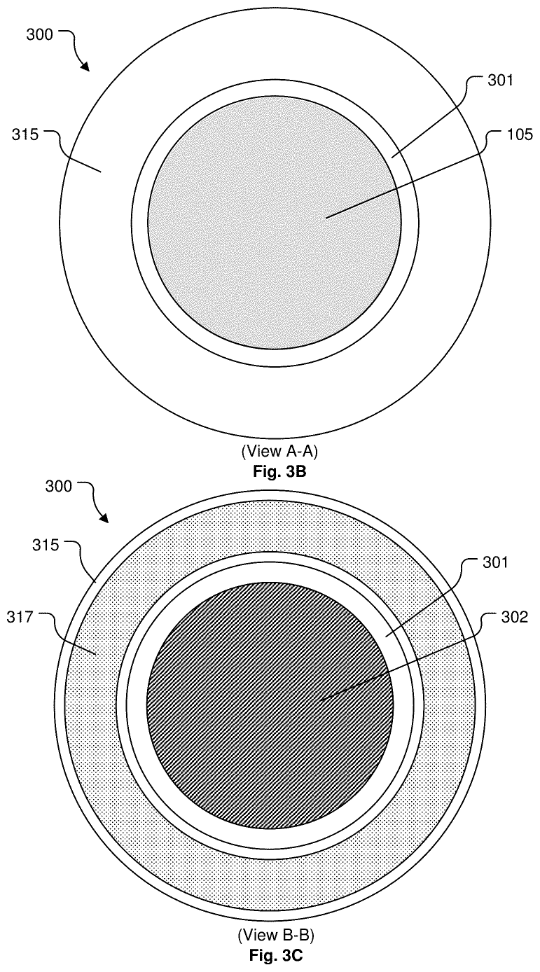

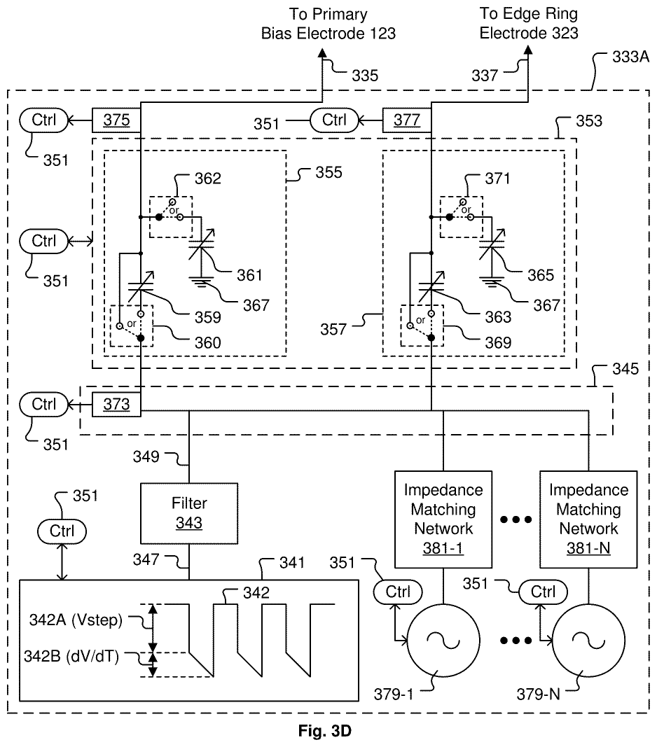

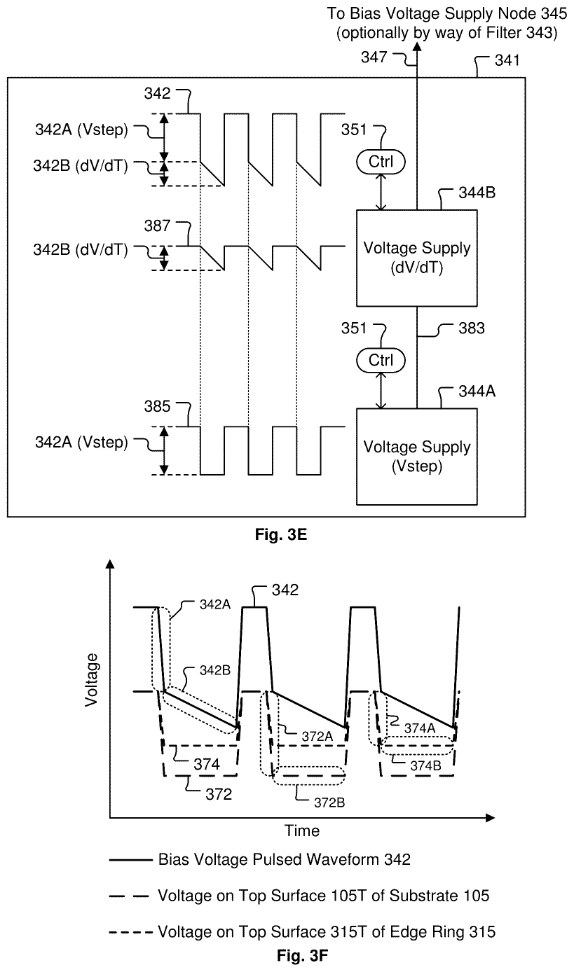

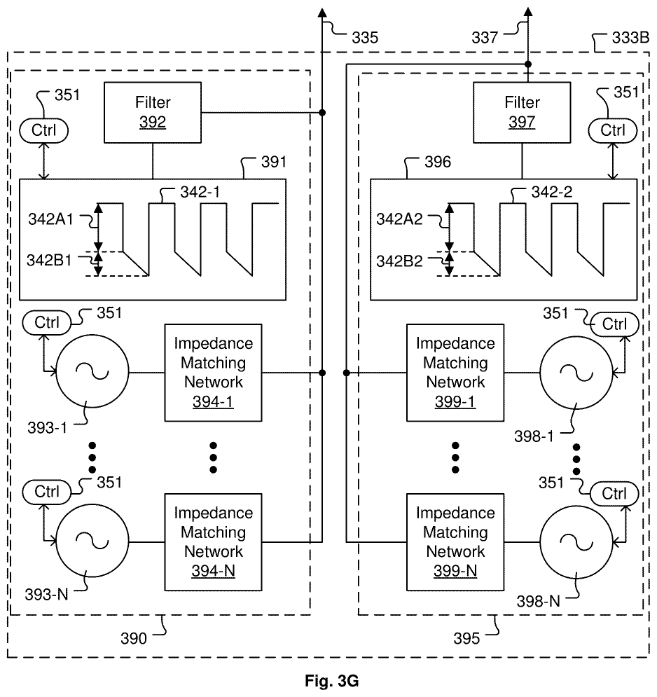

FIG. 3A shows a vertical cross-section view through a plasma processing system 300, in accordance with some embodiments. The plasma processing system 300 is a modification of the plasma processing system 100 of FIG. 1A. The plasma processing system 300 includes the chamber 101, the window 107, and the plasma processing region 102 within the chamber 101. The plasma processing system 300 also includes the TCP RF generator 113, the impedance matching network 111, the connection 115, and the coil 109 disposed above the window 107. The plasma processing chamber 300 also provides for supply of process gases into the plasma processing region 102, as indicated by arrow 117, and removal of process gases and byproduct materials from the plasma processing region 102, as indicated by arrows 121. The RF power supplied from TCP RF generator 113 to the plasma processing region 102, by way of the coil 109 and the RF-transparent window 107, transforms the process gas into the plasma 119 within the plasma processing region 102 in exposure to the substrate 105.

The plasma processing system 300 includes a substrate support 301 that is a modification of the substrate support 103 described with regard to FIG. 1A. The substrate support 301 has a top surface 301T configured to support the substrate 105 during processing. In some embodiments, the substrate support 301 is an electrostatic chuck configured to generate an electrostatic force that holds the substrate 105 to the top surface 301T of the substrate support 301. The substrate support 301 also includes the bias electrode 123 disposed within the substrate support 301 below the top surface 301T of the substrate support 301. In some embodiments, the substrate support 301 is formed of a dielectric material, such as a ceramic material or other type of dielectric material, with the bias electrode 123 formed of an electrically conductive material. In the substrate support 301, the bias electrode 123 is configured to apply a bias voltage to the top surface 105T of the substrate 105 to attract or repel electrically charged constituents of the plasma 119 toward or away from the substrate 105.

In the plasma processing system 300, an edge ring 315 surrounds the substrate support 301, such that the top surface 301T of the substrate support 301 is circumscribed by the edge ring 315. FIG. 3B shows a top view of the substrate 105 disposed on the substrate support 301, with the edge ring 315 surrounding the substrate support 301, referenced as View A-A in FIG. 3A, in accordance with some embodiments. An edge ring electrode 323 is disposed within the edge ring 315. In some embodiments, the edge ring 315 is formed of a dielectric material, with the edge ring electrode 323 formed of an electrically conductive material. In some embodiments, the substrate support 301 extends radially outward below the edge ring 315, such that an outer radial portion of the substrate support 301 provides a support structure upon which the edge ring 315 is disposed. However, regardless of how the edge ring 315 is vertically supported, it should be understood that the edge ring 315 circumscribes the top surface 301T of the substrate support 301.

The bias electrode 123 is electrically connected to a bias voltage supply system 333, as indicated by connection 335. The edge ring electrode 323 is also electrically connected to the bias voltage supply system 333, as indicated by connection 337. The bias voltage supply system 333 is configured to control a voltage on the bias electrode 123 and a voltage on the edge ring electrode 323. The bias electrode 123 is configured to control a voltage on the top surface 105T of the substrate 105 when the substrate 105 is present on the top surface 301T of the substrate support 301. The voltage applied to the bias electrode 123 may be different than the corresponding voltage on the top surface 105T of the substrate 105 due to various materials present between the bias electrode 123 and the top surface 105T of the substrate 105, such as the combination of the dielectric material and other materials present within the substrate support 301 above the bias electrode 123 and the materials of the substrate 105 itself. In some embodiments, the materials present between the bias electrode 123 and the top surface 105T of the substrate 105 can be electrically represented as a substantially fixed capacitance. A voltage measurement device 311 is connected to measure a voltage on the bias electrode 123, as indicated by a connection 313.

In addition to the bias electrode 123, the substrate support 301 also includes a mid-level electrode 302. The mid-level electrode 302 is disposed within the substrate support 301 such that a lower portion 303 of the substrate support 301 is present between the bias electrode 123 and the mid-level electrode 302, and such that an upper portion 305 of the substrate support 301 is present between the mid-level electrode 302 and the top surface 301T of the substrate support 301. In some embodiments, the mid-level electrode 302 is disposed close to where the clamping voltage is applied to hold the substrate 105 on the substrate support 301. In various embodiments, the mid-level electrode 302 can be configured in different ways. For example, in some embodiments, the mid-level electrode 302 is substantially disc-shaped. In some embodiments, the mid-level electrode 302 has a grating shape. In some embodiments, the mid-level electrode 302 has a spoked shape. In some embodiments, the mid-level electrode 302 is configured as a set of concentrically spaced apart annular rings. It should be understood that the mid-level electrode 302 can be configured in essentially any manner, so long as the voltage measured on the mid-level electrode 302 is representative of the voltage present across/through the substrate support 301 at the vertical position of the mid-level electrode 302 within the substrate support 301. In some embodiments, one or more clamping electrodes disposed within the substrate support 301 are used as the mid-level electrode 302, where a known clamping voltage is applied to the one or more clamping electrodes to generate an electrostatic attractive force that holds the substrate 105 on the substrate support 301. A voltage measurement device 307 is connected to measure a voltage on the mid-level electrode 302, as indicated by a connection 309.

The edge ring electrode 323 is configured to control a voltage on a top surface 315T of the edge ring 315. The voltage applied to the edge ring electrode 323 may be different than the corresponding voltage on the top surface 315T of the edge ring 315 due to the dielectric material and other materials present within the edge ring 315 above the edge ring electrode 323. In some embodiments, the materials present between the edge ring electrode 323 and the top surface 315T of the edge ring 315 can be electrically represented as a substantially fixed capacitance. A voltage measurement device 325 is connected to measure a voltage on the edge ring electrode 323, as indicated by a connection 327.

In addition to the edge ring electrode 323, the edge ring 315 also includes an edge ring mid-level electrode 317. The edge ring mid-level electrode 317 is disposed within the edge ring 315 such that a lower portion 319 of the edge ring 315 is present between the edge ring electrode 323 and the edge ring mid-level electrode 317, and such that an upper portion 321 of the edge ring 315 is present between the edge ring mid-level electrode 317 and the top surface 315T of the edge ring 315. A voltage measurement device 329 is connected to measure a voltage on the edge ring mid-level electrode 317, as indicated by a connection 331. In various embodiments, the edge ring mid-level electrode 317 can be configured in different ways. For example, in some embodiments, the edge ring mid-level electrode 317 is shaped as an annular ring. In some embodiments, the edge ring mid-level electrode 317 has a grating/spoked shape with one or more annular rings electrically connected to a set of spaced apart radially oriented grating/spoke structures. In some embodiments, the edge ring mid-level electrode 317 is configured as a set of concentrically spaced apart annular rings. It should be understood that the edge ring mid-level electrode 317 can be configured in essentially any manner, so long as the voltage measured on the edge ring mid-level electrode 317 is representative of the voltage present across/through the edge ring 315 at the vertical position of the edge ring mid-level electrode 317 within the edge ring 315.

FIG. 3C shows a top view of the mid-level electrode 302 within the substrate support 301 and the edge ring mid-level electrode 317 within the edge ring 315, referenced as View B-B in FIG. 3A, in accordance with some embodiments. In some embodiments, the voltage measurement devices 311, 325, 307, and 329 and associated connections 313, 327, 309, and 331, respectively, are part of a voltage measurement system of the bias voltage supply system 333. In some embodiments, the mid-level electrode 302 within the substrate support 301 and the edge ring mid-level electrode 317 within the edge ring 315 are at a substantially equal vertical height within the plasma processing system 300, such as depicted in FIG. 3A. However, in some embodiments, the mid-level electrode 302 within the substrate support 301 and the edge ring mid-level electrode 317 within the edge ring 315 are at different vertical heights within the plasma processing system 300.

FIG. 3D shows a bias voltage supply system 333A that is an example implementation of the bias voltage supply system 333 of FIG. 3A, in accordance with some embodiments. The bias electrode 123 and the edge ring electrode 323, along with their associated electrical connections 335 and 337, respectively, can be considered as components of the bias voltage supply system 333A. The bias voltage supply system 333A includes a voltage supply system 341 having an output electrically connected through a filter 343 to a bias voltage supply node 345, as indicated by connections 347 and 349. The voltage supply system 341 is configured to generate a prescribed bias voltage tailored waveform 342 as a function of time on the bias voltage supply node 345. In some embodiments, the prescribed bias voltage tailored waveform 342 includes a bias voltage step portion (Vstep) 342A and a temporally varying bias voltage portion (dV/dT) 342B. In some embodiments, the prescribed bias voltage tailored waveform 342 is defined as an ongoing series of pulse cycles, where each pulse cycle includes an on-duration and an off-duration. The voltage supply system 341 is connected in bidirectional data/signal communication with a controller 351 that is programmable to direct operation of the voltage supply system 341 to generate essentially any form of prescribed bias voltage tailored waveform 342 as required for a particular plasma processing operation on the substrate 105.

FIG. 3E shows an example implementation of the voltage supply system 341, in accordance with some embodiments. The voltage supply system 341 includes a first voltage supply 344A and a second voltage supply 344B, electrically connected in series with each other, such that their output voltages combine in sum. In some embodiments, each of the first voltage supply 344A and the second voltage supply 344B is a direct current voltage supply. The first voltage supply 344A is configured to generate a temporally constant voltage magnitude in accordance with a prescribed pulse schedule corresponding to the prescribed bias voltage tailored waveform 342. For example, FIG. 3E shows an example pulsed voltage waveform 385 generated and output by the first voltage supply 344A, which will eventually become the bias voltage step portion (Vstep) 342A of the prescribed bias voltage tailored waveform 342. An output of the first voltage supply 344A is electrically connected to an input of the second voltage supply 344B, as indicated by electrical connection 383. An output of the second voltage supply 344B is electrically connected to the output of the voltage supply system 341, as indicated by the electrical connection 347. The second voltage supply 344B is configured to generate a temporally varying pulsed voltage waveform 387, which will eventually become the temporally varying bias voltage portion (dV/dT) 342B of the prescribed bias voltage tailored waveform 342. In some embodiments, the temporally varying pulsed voltage waveform 387 varies substantially linearly as a function of time during the on-duration of each pulse cycle. Also, in some embodiments, the temporally varying pulsed voltage waveform 387 increases in magnitude in a substantially linear manner as a function of time during the on-duration of each pulse cycle. At the output of the second voltage supply 344B, the pulsed voltage waveform 385 is combined with the temporally varying pulsed voltage waveform 387 to generate the prescribed bias voltage tailored waveform 342. In this manner, the output voltage provided by the voltage supply system 341 to the bias voltage supply node 345 is the combination of the pulsed voltage waveform 385 generated by the first voltage supply 344A and the pulsed voltage waveform 387 generated by the second voltage supply 344B. Each of the first voltage supply 344A and the second voltage supply 344B is connected in bidirectional data/signal communication with the controller 351, with the controller 351 directing operation of the first voltage supply 344A and the second voltage supply 344B to synchronize the phases and the duty cycles of the pulsed voltage waveforms 385 and 387 in order to generate the prescribed bias voltage tailored waveform 342.

With reference back to FIG. 3D, the bias voltage supply system 333A includes a splitting circuit 353 configured to apply voltage present on the bias voltage supply node 345 to each of the bias electrode 123 and the edge ring electrode 323 in a controlled manner. The splitting circuit 353 includes a first branch circuit 355 and a second branch circuit 357. The first branch circuit 355 is electrically connected between the bias voltage supply node 345 and the bias electrode 123. The first branch circuit 355 includes a series capacitor 359 and a shunt capacitor 361. In some embodiments, each of the series capacitor 359 and the shunt capacitor 361 is a respective variable capacitor that can have its capacitance setting controlled remotely by way of the controller 351 that is in bidirectional data/signal communication with the splitting circuit 353. In some embodiments, the first branch circuit 355 includes a switching device 360 implemented to enable bypassing of the series capacitor 359, such that the bias voltage supply node 345 can be switchably electrically connected to either an input terminal of the series capacitor 359 or directly to the bias electrode 123 by way of the electrical connection 335. In this manner, the switching device 360 is controlled to either make the series capacitor 359 be serially electrically connected between the bias voltage supply node 345 and the bias electrode 123, or effectively electrically remove the series capacitor 359 from being disposed between the bias voltage supply node 345 and the bias electrode 123. Also, in some embodiments, the first branch circuit 355 includes a switching device 362 implemented so that the shunt capacitor 361 can be electrically connected to or disconnected from the electrical connection 335 that extends from the output of the first branch circuit 355 to the bias electrode 123. In this manner, the switching device 362 is controlled to either electrically connect the shunt capacitor 361 between the bias electrode 123 and a reference ground potential 367, or effectively electrically remove the shunt capacitor 361 from the first branch circuit 355.

The second branch circuit 357 is electrically connected between the bias voltage supply node 345 and the edge ring electrode 323. The second branch circuit 357 includes a series capacitor 363 and a shunt capacitor 365. In some embodiments, each of the series capacitor 363 and the shunt capacitor 365 is a respective variable capacitor that can have its capacitance setting controlled remotely by way of the controller 351 that is in bidirectional data/signal communication with the splitting circuit 353. In some embodiments, the second branch circuit 357 includes a switching device 369 implemented to enable bypassing of the series capacitor 363, such that the bias voltage supply node 345 can be switchably electrically connected to either an input terminal of the series capacitor 363 or directly to the edge ring electrode 323 by way of the electrical connection 337. In this manner, the switching device 369 is controlled to either make the series capacitor 363 be serially electrically connected between the bias voltage supply node 345 and the edge ring electrode 323, or effectively electrically remove the series capacitor 363 from being disposed between the bias voltage supply node 345 and the edge ring electrode 323. Also, in some embodiments, the second branch circuit 357 includes a switching device 371 implemented so that the shunt capacitor 365 can be electrically connected to or disconnected from the electrical connection 337 that extends from the output of the second branch circuit 357 to the edge ring electrode 323. In this manner, the switching device 371 is controlled to either electrically connect the shunt capacitor 365 between the edge ring electrode 323 and the reference ground potential 367, or effectively electrically remove the shunt capacitor 365 from the second branch circuit 357.

In some embodiments, the first branch circuit 355 is configured so that the series capacitor 359 and the shunt capacitor 361 are disengaged, and the second branch circuit 357 is configured so that the series capacitor 363 and the shunt capacitor 365 are engaged. More specifically, in these embodiments, the switching devices 360 and 362 are set so that the bias voltage supply node 345 is directly electrically connected to the bias electrode 123, and the switching devices 369 and 371 are set so that the bias voltage conveyed from the bias voltage supply node 345 to the edge ring electrode 323 is controlled by the series capacitor 363 and the shunt capacitor 365. Thus, in these embodiments, the bias voltage tailored waveform 342 output by the voltage supply system 341 is supplied to the bias electrode 123, and a modified version of the bias voltage tailored waveform 342 output by the voltage supply system 341 is supplied to the edge ring electrode 323.

In some embodiments, the first branch circuit 355 is configured so that the series capacitor 359 and the shunt capacitor 361 are engaged, and the second branch circuit 357 is configured so that the series capacitor 363 and the shunt capacitor 365 are engaged. More specifically, in these embodiments, the switching devices 360 and 362 are set so that the bias voltage conveyed from the bias voltage supply node 345 to the bias electrode 123 is controlled by the series capacitor 359 and the shunt capacitor 361, and the switching devices 369 and 371 are set so that the bias voltage conveyed from the bias voltage supply node 345 to the edge ring electrode 323 is controlled by the series capacitor 363 and the shunt capacitor 365. Thus, in these embodiments, a first modified version of the bias voltage tailored waveform 342 output by the voltage supply system 341 is supplied to the bias electrode 123, and a second modified version of the bias voltage tailored waveform 342 output by the voltage supply system 341 is supplied to the edge ring electrode 323.

Additionally, in some embodiments, the series capacitor 359 can be engaged in the first branch circuit 355, with the shunt capacitor 361 disengaged. In some embodiments, the shunt capacitor 361 can be engaged in the first branch circuit 355, with the series capacitor 359 disengaged. Also, in some embodiments, the series capacitor 363 can be engaged in the second branch circuit 357, with the shunt capacitor 365 disengaged. In some embodiments, the shunt capacitor 365 can be engaged in the second branch circuit 357, with the series capacitor 363 disengaged.

In some embodiments a voltage sensor 373, e.g., voltage/current sensor (VI sensor), is connected to measure the real-time voltage on the bias voltage supply node 345, and convey information related to this measured voltage to the controller 351. In some embodiments a voltage sensor 375, e.g., voltage/current sensor (VI sensor), is connected to measure the real-time voltage at the output of the first branch circuit 355, and convey information related to this measured voltage to the controller 351. In some embodiments a voltage sensor 377, e.g., voltage/current sensor (VI sensor), is connected to measure the real-time voltage at the output of the second branch circuit 357, and convey information related to this measured voltage to the controller 351. In various embodiments, the controller 351 is configured to use the voltages measured by one or more of the voltage sensors 373, 375, and 377 as feedback signal(s) for controlling operation of the voltage supply system 341 and one or more of the series capacitor 359, the shunt capacitor 361, the series capacitor 363, and the shunt capacitor 365.

Also, in some embodiments, the bias voltage supply system 333A includes a number (N) of RF generators 379-1 to 379-N, where N is greater than or equal to 1, connected to supply RF bias voltage to the bias voltage supply node 345 by way of a respective impedance matching network 381-1 to 381-N. Each of the RF generators 379-1 to 379-N is connected in bidirectional data/signal communication with the controller 351. At the bias voltage supply node 345, the RF voltage signal(s) output by the RF generators 379-1 to 379-N combine with the bias voltage tailored waveform 342 output by the voltage supply system 341. The RF generators 379-1 to 379-N and corresponding impedance matching networks 381-1 to 381-N are implemented in some embodiments of the bias voltage supply system 333A. However, in other embodiments of the bias voltage supply system 333A, the RF generators 379-1 to 379-N and corresponding impedance matching networks 381-1 to 381-N are not implemented.

FIG. 3F shows an example bias voltage tailored waveform 342 generated by the voltage supply system 341, and a corresponding bias voltage waveform 372 on the top surface 105T of the substrate 105, and a corresponding bias voltage waveform 374 on the top surface 315T of the edge ring 315, in accordance with some embodiments. The bias voltage tailored waveform 342 includes the bias voltage step portion (Vstep) 342A and the temporally varying bias voltage portion (dV/dT) 342B. The bias voltage tailored waveform 342 is generated on the bias voltage supply node 345. Therefore, the bias voltage waveform 372 on the top surface 105T of the substrate 105 is based on the bias voltage tailored waveform 342 as modified by the first branch circuit 355. Similarly, the bias voltage waveform 374 on the top surface 315T of the edge ring 315 is based on the bias voltage tailored waveform 342 as modified by the second branch circuit 357. The bias voltage waveform 372 includes a step portion 372A and a slope portion 372B. The bias voltage waveform 374 includes a step portion 374A and a slope portion 374B.

The shunt capacitor 361 in the first branch circuit 355 controls the magnitude of the step portion 372A of the bias voltage waveform 372 on the top surface 105T of the substrate 105. Specifically, the capacitance setting of the shunt capacitor 361 can be controlled to set the magnitude of the step portion 372A at a percentage (0 to 100%) of the magnitude of the bias voltage step portion (Vstep) 342A. If the shunt capacitor 361 is disengaged (or not present) in the first branch circuit 355, the magnitude of the step portion 372A is a fixed percentage of the magnitude of the bias voltage step portion (Vstep) 342A, depending on the intrinsic capacitive effect of the materials of the substrate support 301 and substrate 105 present between the bias electrode 123 and the top surface 105T of the substrate 105. The above-mentioned fixed percentage of the magnitude of the bias voltage step portion (Vstep) 342A is dependent on the structure between the output of the voltage supply system 341 and the top surface 105T of the substrate 105. For example, there may be stray shunt capacitances in structures such as the filter 343, the impedance matching networks 381-1 to 381-N, and the electrical connections 347, 349, 345, and 335. Also, when the rising time of the bias voltage step portion (Vstep) 342A is relatively long compared to the ion travel time through the plasma sheath, series capacitances between the output of the voltage supply system 341 and the top surface 105T of the substrate 105 can reduce the above-mentioned fixed percentage of the magnitude of Vstep 342A due to the ion flux during the rising time of Vstep 342A. For example, in some embodiments, various series capacitances may be inserted for some purpose in the filter 343, the substrate support 301, the substrate 105, and/or the electrical connections 347, 349, 345, and 335. The reduction in the above-mentioned fixed percentage of the magnitude of Vstep 342A due to series capacitances can be mostly eliminated by having a relatively short rising time of Vstep 342A, e.g., Vstep«1 microsecond.

The series capacitor 359 in the first branch circuit 355 controls the slope (change in voltage with respect to time) of the slope portion 372B of the bias voltage waveform 372 on the top surface 105T of the substrate 105. When voltage is applied to the bias electrode 123 there is an ion current toward the top surface 105T of the substrate 105 from the plasma 119, which discharges the negative charges on the top surface 105T of the substrate 105 and correspondingly causes a decrease in the magnitude of the negative voltage on the top surface 105T of the substrate 105 over time. In order to compensate for this ion-induced decrease in magnitude of the negative voltage on the top surface 105T of the substrate 105, the temporally varying bias voltage portion (dV/dT) 342B of the bias voltage tailored waveform 342 provides an increase in bias voltage over time. The capacitance setting of the series capacitor 359 is controlled to tune the change in bias voltage as a function of time on the top surface 105T of the substrate 105 to compensate for the ion-induced discharge of the negative charges on the top surface 105T of the substrate 105. In some embodiments, the capacitance setting of the series capacitor 359 is controlled to maintain a substantially constant voltage on the top surface 105T of the substrate 105 during the on-duration of the bias voltage tailored waveform 342. However, in other embodiments, the capacitance setting of the series capacitor 359 is controlled to achieve a desired change in voltage as a function of time (positive dV/dT and/or negative dV/dT) on the top surface 105T of the substrate 105 during the on-duration of the bias voltage tailored waveform 342. If the series capacitor 359 is disengaged/bypassed (or not present) in the first branch circuit 355, the change in voltage as a function of time (dV/dT) on the top surface 105T of the substrate 105 during the on-duration of the bias voltage tailored waveform 342 will follow the temporally varying bias voltage portion (dV/dT) 342B of the bias voltage tailored waveform 342, with a fixed voltage magnitude offset based on the intrinsic capacitive effect of the materials of the substrate support 301 and substrate 105 present between the bias electrode 123 and the top surface 105T of the substrate 105. In some embodiments, the above-mentioned fixed voltage magnitude offset can also be based on the intrinsic series capacitances between the output of the voltage supply system 341 and the top surface 105T of the substrate 105. In some embodiments, the above-mentioned intrinsic series capacitances correspond to various series capacitances inserted for some purpose in the filter 343, the substrate support 301, the substrate 105, and/or the electrical connections 347, 349, 345, and 335.

The shunt capacitor 365 in the second branch circuit 357 controls the magnitude of the step portion 374A of the bias voltage waveform 374 on the top surface 315T of the edge ring 315. Specifically, the capacitance setting of the shunt capacitor 365 can be controlled to set the magnitude of the step portion 374A at a percentage (0 to 100%) of the magnitude of the bias voltage step portion (Vstep) 342A. If the shunt capacitor 365 is disengaged (or not present) in the second branch circuit 357, the magnitude of the step portion 374A is a fixed percentage of the magnitude of the bias voltage step portion (Vstep) 342A, depending on the intrinsic capacitive effect of the edge ring 315 material present between the edge ring electrode 323 and the top surface 315T of the edge ring 315. In some embodiments, the magnitude of the step portion 374A can also be based on the intrinsic series capacitances between the output of the voltage supply system 341 and the top surface 315T of the edge ring 315. In some embodiments, the above-mentioned intrinsic series capacitances correspond to various series capacitances inserted for some purpose in the filter 343, the edge ring 315, and/or the electrical connections 347, 349, 345, and 337.

The series capacitor 363 in the second branch circuit 357 controls the slope (change in voltage with respect to time) of the slope portion 374B of the bias voltage waveform 374 on the top surface 315T of the edge ring 315. When voltage is applied to the edge ring electrode 323 there is an ion current toward the top surface 315T of the edge ring 315 from the plasma 119, which discharges the negative charges on the top surface 315T of the edge ring 315 and correspondingly causes a decrease in the magnitude of the negative voltage on the top surface 315T of the edge ring 315 over time. In order to compensate for this ion-induced decrease in magnitude of the negative voltage on the top surface 315T of the edge ring 315, the temporally varying bias voltage portion (dV/dT) 342B of the bias voltage tailored waveform 342 provides an increase in bias voltage over time. The capacitance setting of the series capacitor 363 is controlled to tune the change in bias voltage as a function of time on the top surface 315T of the edge ring 315 to compensate for the ion-induced discharge of the negative charges on the top surface 315T of the edge ring 315. In some embodiments, the capacitance setting of the series capacitor 363 is controlled to maintain a substantially constant voltage on the top surface 315T of the edge ring 315 during the on-duration of the bias voltage tailored waveform 342. However, in other embodiments, the capacitance setting of the series capacitor 363 is controlled to achieve a desired change in voltage as a function of time (positive dV/dT and/or negative dV/dT) on the top surface 315T of the edge ring 315 during the on-duration of the bias voltage tailored waveform 342. If the series capacitor 363 is disengaged/bypassed (or not present) in the second branch circuit 357, the change in voltage as a function of time (dV/dT) on the top surface 315T of the edge ring 315 during the on-duration of the bias voltage tailored waveform 342 will follow the temporally varying bias voltage portion (dV/dT) 342B of the bias voltage tailored waveform 342, with a fixed voltage magnitude offset based on the intrinsic capacitive effect of the edge ring 315 material present between the edge ring electrode 323 and the top surface 315T of the edge ring 315. In some embodiments, the above-mentioned fixed voltage magnitude offset can also be based on the intrinsic series capacitances between the output of the voltage supply system 341 and the top surface 315T of the edge ring 315. In some embodiments, the above-mentioned intrinsic series capacitances correspond to various series capacitances inserted for some purpose in the filter 343, the edge ring 315, and/or the electrical connections 347, 349, 345, and 337.

FIG. 3G shows a bias voltage supply system 333B that is an example implementation of the bias voltage supply system 333 of FIG. 3A, in accordance with some embodiments. The bias voltage supply system 333B includes a first voltage supply system 390 and a second voltage supply system 395. The first voltage supply system 390 includes a voltage supply system 391 having an output connected to the bias electrode 123 by way of a filter 392 and the electrical connection 335. The voltage supply system 391 is configured in the same way as the voltage supply system 341. Therefore, the voltage supply system 391 generates and supplies a prescribed bias voltage tailored waveform 342-1 to the bias electrode 123. The prescribed bias voltage tailored waveform 342-1 includes a step portion 342A1 and a slope portion 342B1. The filter 392 is configured to prevent RF signals from entering into the voltage supply system 391. In various embodiments, the filter 392 is a low-pass filter or notch filter.

The first voltage supply system 390 also optionally includes a number (N) of RF generators 393-1 to 393-N, where N is greater than or equal to 1, connected to supply RF bias voltage to the bias electrode 123 by way of a respective impedance matching network 394-1 to 394-N. Each of the RF generators 393-1 to 393-N is connected in bidirectional data/signal communication with the controller 351. The controller 351 operates to synchronize bias voltage waveforms output by the voltage supply system 391 and each of the RF generators 393-1 to 393-N. The RF voltage signal(s) output by the RF generators 393-1 to 393-N combine with the bias voltage tailored waveform 342-1 output by the voltage supply system 391 on the electrical connection 335. The RF generators 393-1 to 393-N and corresponding impedance matching networks 394-1 to 394-N are implemented in some embodiments of the first voltage supply system 390. However, in some embodiments, the RF generators 393-1 to 393-N and corresponding impedance matching networks 394-1 to 394-N are not implemented in the first voltage supply system 390.

The second voltage supply system 395 includes a voltage supply system 396 having an output connected to the edge ring electrode 323 by way of a filter 397 and the electrical connection 337. The voltage supply system 396 is configured in the same way as the voltage supply system 341. Therefore, the voltage supply system 396 generates and supplies a prescribed bias voltage tailored waveform 342-2 to the edge ring electrode 323. The prescribed bias voltage tailored waveform 342-2 includes a step portion 342A2 and a slope portion 342B2. The filter 397 is configured to prevent RF signals from entering the voltage supply system 396. In various embodiments, the filter 397 is a low-pass filter or notch filter.

The second voltage supply system 395 also optionally includes a number (N) of RF generators 398-1 to 398-N, where N is greater than or equal to 1, connected to supply RF bias voltage to the edge ring electrode 323 by way of a respective impedance matching network 399-1 to 399-N. Each of the RF generators 398-1 to 398-N is connected in bidirectional data/signal communication with the controller 351. The controller 351 operates to synchronize bias voltage waveforms output by the voltage supply system 396 and each of the RF generators 398-1 to 398-N. The RF voltage signal(s) output by the RF generators 398-1 to 398-N combine with the bias voltage tailored waveform 342-2 output by the voltage supply system 396 on the electrical connection 337. The RF generators 398-1 to 398-N and corresponding impedance matching networks 399-1 to 399-N are implemented in some embodiments of the second voltage supply system 395. However, in some embodiments, the RF generators 398-1 to 398-N and corresponding impedance matching networks 399-1 to 399-N are not implemented in the second voltage supply system 395.

In some embodiments, the bias voltage tailored waveform 342-1 is generated to maintain a substantially constant voltage on the top surface 105T of the substrate 105 during the on-duration of each pulse cycle within the bias voltage tailored waveform 342-1, and the bias voltage tailored waveform 342-2 is generated to maintain a substantially constant voltage on the top surface 315T of the edge ring 315 during the on-duration of each pulse cycle within the bias voltage tailored waveform 342-2, such that a substantially constant voltage differential is maintained during the concurrent on-durations of the pulse cycles in the bias voltage tailored waveforms 342-1 and 342-2, where the substantially constant voltage differential is defined to maintain a substantially flat plasma sheath boundary across the transition between the substrate 105 and the edge ring 315. In some embodiments, the step portion 342A1 of the bias voltage tailored waveform 342-1 and the step portion 342A2 of the bias voltage tailored waveform 342-2 are synchronously controlled to achieve a prescribed voltage differential between the top surface 105T of the substrate 105 and the top surface 315T of the edge ring 315. Also, in some embodiments, the slope portion 342B1 of the bias voltage tailored waveform 342-1 is controlled to compensate for ion-induced discharge of negative charges on the top surface 105T of the substrate 105 over the on-duration of each pulse cycle of the bias voltage tailored waveform 342-1, such that the voltage on the top surface 105T of the substrate 105 remains substantially constant over the on-duration of each pulse cycle of the bias voltage tailored waveform 342-1. Also, in some embodiments, the slope portion 342B2 of the bias voltage tailored waveform 342-2 is controlled to compensate for ion-induced discharge of negative charges on the top surface 315T of the edge ring 315 over the on-duration of each pulse cycle of the bias voltage tailored waveform 342-2, such that the voltage on the top surface 315T of the edge ring 315 remains substantially constant over the on-duration of each pulse cycle of the bias voltage tailored waveform 342-2.

In some embodiments, the controller 351 operates to synchronize the phase of the bias voltage tailored waveforms 342-1 and 342-2. In some embodiments, the controller 351 operates to synchronize both the phase and duty cycle of the bias voltage tailored waveforms 342-1 and 342-2. In some embodiments, the controller 351 operates to implement a prescribed phase shift between the bias voltage tailored waveforms 342-1 and 342-2. In some embodiments, the bias voltage tailored waveforms 342-1 and 342-2 are defined to have a different phase and/or a different duty cycle with respect to each other. Also, in some embodiments, one or both of the bias voltage tailored waveforms 342-1 and 342-2 is/are defined to implement a prescribed level-to-level pulsing scheme. It should be understood that the bias voltage tailored waveforms 342-1 and 342-2 are separately and independently controllable with respect to each other.

Additionally, in various embodiments, any number of voltage sensors, e.g., voltage/current sensors (VI sensors), can be connected within the bias voltage supply system 333B to measure real-time voltage at a particular location, and convey information related to this measured real-time voltage to the controller 351. In some embodiments, the controller 351 is configured to use real-time voltage measurements within the first voltage supply system 390 and/or the second voltage supply system 395 to control operation of any one or more of the voltage supply system 391, the RF generators 393-1 to 393-N, the voltage supply system 396, and the RF generators 398-1 to 398-N.

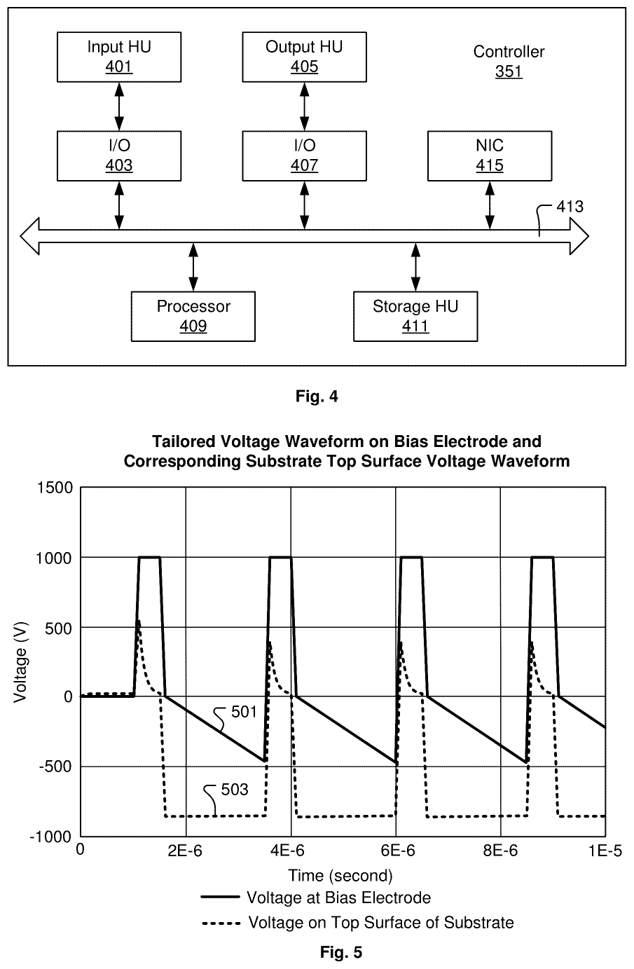

FIG. 4 shows an example diagram of the controller 351, in accordance with some embodiments. In some embodiments, the controller 351 includes a processor 409, a storage hardware unit (HU) 411 (e.g., memory), an input HU 401, an output HU 405, an input/output (I/O) interface 403, an I/O interface 407, a network interface controller (NIC) 415, and a data communication bus 413. The processor 409, the storage HU 411, the input HU 401, the output HU 405, the I/O interface 403, the I/O interface 407, and the NIC 415 are in data communication with each other by way of the data communication bus 413. Examples of the input HU 401 include a mouse, a keyboard, a stylus, a data acquisition system, a data acquisition card, etc. Examples of the output HU 405 include a display, a speaker, a device controller, etc. Examples of the NIC 415 include a network interface card, a network adapter, etc. In various embodiments, the NIC 415 is configured to operate in accordance with one or more communication protocols and associated physical layers, such as Ethernet and/or EtherCAT, among others. Each of the I/O interfaces 403 and 407 is defined to provide compatibility between different hardware units coupled to the I/O interface. For example, the I/O interface 403 can be defined to convert a signal received from the input HU 401 into a form, amplitude, and/or speed compatible with the data communication bus 413. Also, the I/O interface 407 can be defined to convert a signal received from the data communication bus 413 into a form, amplitude, and/or speed compatible with the output HU 405. Although various operations described herein are performed by the processor 409 of the controller 351, it should be understood that in some embodiments various operations can be performed by multiple processors of the controller 351 and/or by multiple processors of multiple computing systems connected to the controller 351.

In various embodiments, the plasma processing system 300 is integrated with electronics for controlling its operation before, during, and after processing of the substrate 105, where the electronics are implemented within the controller 351 that is configured and connected to control various components and/or sub-parts of the plasma processing system 300, including the bias voltage supply system 333. Depending on substrate 105 processing requirements and/or the particular configuration of the plasma processing system 300, the controller 351 is programmed to control any process and/or component disclosed herein, including delivery of process gas(es), temperature settings (e.g., heating and/or cooling), pressure settings, vacuum settings, power settings, RF power supply system settings, electrical signal frequency settings, gas flow rate settings, fluid delivery settings, positional and operation settings, bias voltage supply system 333 settings, substrate 105 transfers into and out of the plasma processing system 300 and/or into and out of load locks connected to or interfaced with the plasma processing system 300, among others.

In various embodiments, the controller 351 is defined as electronics having various integrated circuits, logic, memory, and/or software that direct and control various tasks/operations, such as receiving instructions, issuing instructions, controlling device operations, enabling cleaning operations, enabling endpoint measurements, enabling metrology measurements (optical, thermal, electrical, etc.), among other tasks/operations. In some embodiments, the integrated circuits within the controller 351 include one or more of firmware that stores program instructions, a digital signal processor (DSP), an Application Specific Integrated Circuit (ASIC) chip, a programmable logic device (PLD), one or more microprocessors, and/or one or more microcontrollers that execute program instructions (e.g., software), among other computing devices. In some embodiments, the program instructions are communicated to the controller 351 in the form of various individual settings (or program files), defining operational parameters for carrying out a process on the substrate 105 within the plasma processing system 300. In some embodiments, the operational parameters are included in a recipe defined by process engineers to accomplish one or more processing steps during the fabrication of one or more layers, materials, metals, oxides, silicon, silicon dioxide, surfaces, circuits, and/or dies on the substrate 105.

In some embodiments, the controller 351 is a part of, or connected to, a computer that is integrated with, or connected to, the plasma processing system 300, or that is otherwise networked to the plasma processing system 300, or a combination thereof. For example, in some embodiments, the controller 351 is implemented in a “cloud” or all or a part of a fab host computer system, which allows for remote access for control of substrate 105 processing by the plasma processing system 300. The controller 351 enables remote access to the plasma processing system 300 to provide for monitoring of current progress of fabrication operations, provide for examination of a history of past fabrication operations, provide for examination of trends or performance metrics from a plurality of fabrication operations, provide for changing of processing parameters, provide for setting of subsequent processing steps, provide for specification of RF power supply system operational parameters, provide for specification of bias voltage supply system 333 operational parameters, and/or provide for initiation of a new substrate fabrication process.

In some embodiments, a remote computer, such as a server computer system, provides process recipes to the controller 351 over a computer network, which includes a local network and/or the Internet. The remote computer includes a user interface that enables entry or programming of parameters and/or settings, which are then communicated to the controller 351 from the remote computer. In some examples, the controller 351 receives instructions in the form of settings for processing the substrate 105 within the plasma processing system 300. It should be understood that the settings are specific to a type of process to be performed on the substrate 105 and a type of tool/device/component that the controller 351 interfaces with or controls. In some embodiments, the controller 351 is distributed, such as by including one or more discrete controller(s) 351 that are networked together and synchronized to work toward a common purpose, such as operating the plasma processing system 300 to perform a prescribed process on the substrate 105. An example of a distributed controller 351 for such purposes includes one or more integrated circuits on a chamber in communication with one or more integrated circuits located remotely (such as at a platform level or as part of a remote computer) that combine to control a process in the chamber.

FIG. 5 shows an example of a bias voltage tailored waveform 501 supplied to the bias electrode 123 by the bias voltage supply system 333, e.g., 333A or 333B, and a corresponding voltage waveform 503 that results on the top surface 105T of the substrate 105, in accordance with some embodiments. The bias voltage tailored waveform 501 is similar to the prescribed bias voltage tailored waveform 342 described with regard to FIG. 3F. Also, the resulting voltage waveform 503 on the top surface 105T of the substrate 105 is similar to the bias voltage waveform 372 described with regard to FIG. 3F. The bias voltage tailored waveform 501 has a pulse shape with a cyclical frequency within the RF regime. It should be understood that the bias voltage tailored waveform 501 is a non-sinusoidal RF waveform. In various embodiments, the bias voltage tailored waveform 501 is configured to control an ion energy distribution function (IEDF) of ions in the plasma 119 within a range of electrical influence extending upward from the top surface 105T of the substrate 105. For example, in FIG. 5, the bias voltage tailored waveform 501 is configured to control the IEDF of ions in the plasma 119 to achieve a substantially monoenergetic ion energy distribution at the top surface 105T of the substrate 105. The bias voltage tailored waveform 501 generates a substantially constant negative voltage on the top surface 105T of the substrate 105, as indicated by the voltage waveform 503, such that ions within the plasma 119 are accelerated to a substantially same energy level as they are attracted toward the top surface 105T of the substrate 105.

Operation of the bias voltage supply system 333 to generate the bias voltage tailored waveform 501 and supply the bias voltage tailored waveform 501 to the bias electrode 123 enables achievement of a narrow IEDF as well as independent control of ion energy and ion flux at the top surface 105T of the substrate 105. However, the control of the IEDF and ion flux at the top surface 105T of the substrate 105 remains a challenge without having a real-time, in-situ measurement of the IEDF and ion flux at the top surface 105T of the substrate 105. Achieving and maintaining a desired IEDF requires detection of either the IEDF or voltage at the top surface 105T of the substrate 105. Because the IEDF is dependent on the voltage at the top surface 105T of the substrate 105, the real-time IEDF at the top surface 105T of the substrate 105 can be determined by knowing the real-time voltage at the top surface 105T of the substrate 105. However, any direct measurement of the IEDF or voltage at the top surface 105T of the substrate 105 would require deployment of a physical sensor or probe on the substrate 105, which would interfere with processing of the substrate 105, e.g., deteriorate plasma 119 uniformity across the substrate 105, among other issues, and correspondingly lead to reduced semiconductor chip manufacturing yield. Use of the non-sinusoidal bias voltage tailored waveform 501 to control of the voltage and the electrical current on the substrate 105 is dependent upon knowing the real-time voltage on the top surface 105T of the substrate 105.

Various embodiments are disclosed herein for real-time indirect measurement of the voltage on the top surface 105T of the substrate 105 to enable real-time closed-loop feedback control of the non-sinusoidal bias voltage tailored waveform 342, 342-1, 501 in order to achieve and maintain a prescribed voltage on the top surface 105T of the substrate 105, and correspondingly control the IEDF at the top surface 105T of the substrate 105. Efficient and accurate detection of the voltage on the top surface 105T of the substrate 105 is important, especially for plasma-based substrate 105 fabrication processes that include pulsing operations in which the plasma 119 density dynamically changes within short period of time (e.g., much less than 1 millisecond). Also, various embodiments are disclosed herein for real-time indirect measurement of the voltage on the top surface 315T of the edge ring 315 to enable real-time closed-loop feedback control of the non-sinusoidal bias voltage tailored waveform 342, 342-2 in order to achieve and maintain a prescribed voltage on the top surface 315T of the edge ring 315, and correspondingly control the IEDF at the top surface 315T of the edge ring 315.

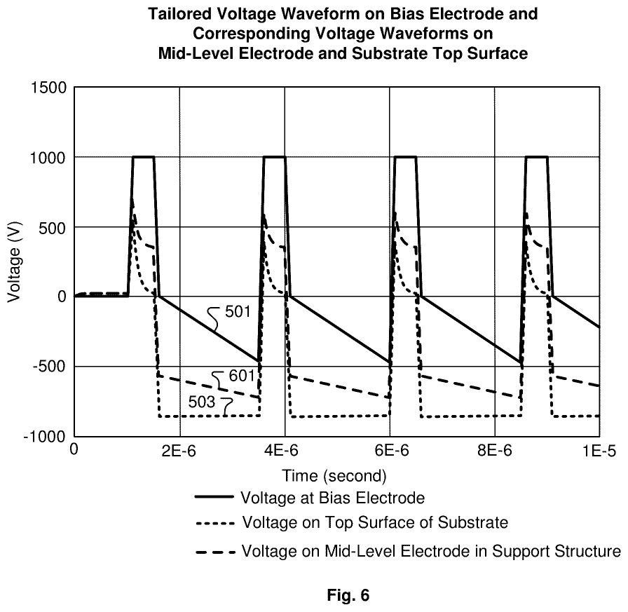

FIG. 6 shows a voltage waveform 601 on the mid-level electrode 302 within the substrate support 301 that corresponds to the bias voltage tailored waveform 501 supplied to the bias electrode 123 by the bias voltage supply system 333, as shown in FIG. 5, in accordance with some embodiments. FIG. 6 also shows the voltage waveform 503 that results on the top surface 105T of the substrate 105 from supply of the bias voltage tailored waveform 501 to the bias electrode 123 by the bias voltage supply system 333, as shown in FIG. 5. The bias electrode 123 voltage is controlled by the bias voltage tailored waveform 342, 342-1, 501 that is supplied to the bias electrode 123 by the bias voltage supply system 333. The voltage on the top surface 105T of the substrate 105 is controlled by both the bias voltage tailored waveform 342, 342-1, 501 that is supplied to the bias electrode 123 by the bias voltage supply system 333, and the electrons and ions from the plasma 119 that are incident on the top surface 105T of the substrate 105. The electrically isolated mid-level electrode 302 that is disposed within the substrate support 301 between the bias electrode 123 and the top surface 301T of the substrate support 301 captures the voltage waveform 601 that is between the bias voltage tailored waveform 342, 342-1, 501 and the voltage waveform 503 on the top surface 105T of the substrate 105.

The voltage difference between the bias electrode 123 and the mid-level electrode 302 is proportional to the impedance between the bias electrode 123 and the mid-level electrode 302. Similarly, the voltage difference between the mid-level electrode 302 and the top surface 105T of the substrate 105 is proportional to the impedance between the mid-level electrode 302 and the top surface 105T of the substrate 105. The impedance between the bias electrode 123 and the mid-level electrode 302 is given by (1/jωC_{midlevel-to-biaselectrode}), where C_{midlevel-to-biaselectrode} is the capacitance of the lower portion 303 of the substrate support 301 between the bias electrode 123 and the mid-level electrode 302. The impedance between the mid-level electrode 302 and the top surface 105T of the substrate 105 is given by (1/jωC_{substrate-to-midlevel}), where C_{substrate-to-midlevel} is the capacitance of the upper portion 305 of the substrate support 301 between the mid-level electrode 302 and the top surface 301T of the substrate support 301. This assumes that the impact of the substrate 105 on the impedance between the mid-level electrode 302 and the top surface 105T of the substrate 105 is negligible. Therefore, the electrically isolated mid-level electrode 302 forms a capacitive divider that picks up the voltage as shown in Equation 1, where V_{midlevel} is the voltage on the mid-level electrode 302, V_{biaselectrode} is the voltage on the bias electrode 123, and V_{substrate} is the voltage on the top surface 105T of the substrate 105. From Equation 1, the voltage on the mid-level electrode 302 can be expressed as shown in Equation 2. Also, from Equation 1, the voltage on the top surface 105T of the substrate 105 can be expressed as shown in Equation 3. Therefore, the real-time voltage (V_{substrate}) on the top surface 105T of the substrate 105 is indirectly determined using Equation 3, with the known capacitance (C_{midlevel-to-biaselectrode}) of the lower portion 303 of the substrate support 301 between the bias electrode 123 and the mid-level electrode 302, and with the known capacitance (C_{substrate-to-midlevel}) of the upper portion 305 of the substrate support 301 between the mid-level electrode 302 and the top surface 301T of the substrate support 301, and with the direct real-time measurements of the voltage (V_{midlevel}) on the mid-level electrode 302 and the voltage (V_{biaselectrode}) on the bias electrode 123.

$$\frac{{V}_{midlevel} - {V}_{biaselectrode}}{{V}_{substrate} - {V}_{midlevel}} = \frac{{C}_{substrate - to - midlevel}}{{C}_{midlevel - to - biaselectrode}} . \qquad Equation 1$$

$$Equation 2$$

$${V}_{midlevel} = \frac{{C}_{substrate - to - midlevel} {V}_{subsrate} + {C}_{midlevel - to - biaselectrode} {V}_{biaselectrode}}{{C}_{substrate - to - midlevel} + {C}_{midlevel - to - biaselectrode}} .$$

$$Equation 3$$

$${V}_{substrate} = {V}_{midlevel} + \frac{{C}_{midlevel - to - biaselectrode}}{{C}_{substrate - to - midlevel}} ( {V}_{midlevel} - {V}_{biaselectrode} ) .$$

The same relationships exhibited in Equations 1 through 3 are applicable to the edge ring 315 for indirectly determining the voltage on the top surface 315T of the edge ring 315 by using direct real-time voltage measurements on each of the edge ring electrode 323 and the edge ring mid-level electrode 317.

The edge ring electrode 323 voltage is controlled by the bias voltage tailored waveform 342, 342-2 that is supplied to the edge ring electrode 323 by the bias voltage supply system 333. The voltage on the top surface 315T of the edge ring 315 is controlled not only by the bias voltage tailored waveform 342, 342-2 that is supplied to the edge ring electrode 323 by the bias voltage supply system 333, but also by the electrons and ions from the plasma 119 that are incident on the top surface 315T of the edge ring 315. The electrically isolated edge ring mid-level electrode 317 that is disposed within the edge ring 315 between the edge ring electrode 323 and the top surface 315T of the edge ring 315 captures the voltage waveform that is between the bias voltage tailored waveform 342, 342-2 and the voltage waveform on the top surface 315T of the edge ring 315.

The voltage difference between the edge ring electrode 323 and the edge ring mid-level electrode 317 is proportional to the impedance between the edge ring electrode 323 and the edge ring mid-level electrode 317. Similarly, the voltage difference between the edge ring mid-level electrode 317 and the top surface 315T of the edge ring 315 is proportional to the impedance between the edge ring mid-level electrode 317 and the top surface 315T of the edge ring 315. The impedance between the edge ring electrode 323 and the edge ring mid-level electrode 317 is given by (1/jωC_{ERmidlevel-to-ERelectrode}), where C_{ERmidlevel-to-ERelectrode} is the capacitance of the lower portion 319 of the edge ring 315 between the edge ring electrode 323 and the edge ring mid-level electrode 317. The impedance between the edge ring mid-level electrode 317 and the top surface 315T of the edge ring 315 is given by (1/jωC_{ERtop-to-ERmidlevel}), where C_{ERtop-to-ERmidlevel} is the capacitance of the upper portion 321 of the edge ring 315 between the edge ring mid-level electrode 317 and the top surface 315T of the edge ring 315. Therefore, the electrically isolated edge ring mid-level electrode 317 forms a capacitive divider that picks up the voltage as shown in Equation 4, where V_{ERmidlevel} is the voltage on the edge ring mid-level electrode 317, V_{ERelectrode} is the voltage on the edge ring electrode 323, and V_{ERtop} is the voltage on the top surface 315T of the edge ring 315. From Equation 4, the voltage on the edge ring mid-level electrode 317 can be expressed as shown in Equation 5. Also, from Equation 4, the voltage on the top surface 315T of the edge ring 315 can be expressed as shown in Equation 6. Therefore, the real-time voltage (V_{ERtop}) on the top surface 315T of the edge ring 315 is indirectly determined using Equation 6, with the known capacitance (C_{ERmidlevel-to-ERelectrode}) of the lower portion 319 of the edge ring 315 between the edge ring electrode 323 and the edge ring mid-level electrode 317, and with the known capacitance (C_{ERtop-to-ERmidlevel}) of the upper portion 321 of the edge ring 315 between the edge ring mid-level electrode 317 and the top surface 315T of the edge ring 315, and with the direct real-time measurements of the voltage (V_{ERmidlevel}) on the edge ring mid-level electrode 317 and the voltage (V_{ERelectrode}) on the edge ring electrode 323.

$$\frac{{V}_{ERmidlevel} - {V}_{ERelectrode}}{{V}_{ERtop} - {V}_{ERmidlevel}} = \frac{{C}_{ERtop - to - ERmidlevel}}{{C}_{ERmidlevel - to - ERelectrode}} . \qquad Equation 4$$

$$Equation 5$$

$${V}_{ERmidlevel} = \frac{{C}_{ERtop - to - ERmidlevel} + {C}_{ERmidlevel - to - ERelectrode} {V}_{ERelectrode}}{{C}_{ERtop - to - ERmidlevel} + {C}_{ERmidlevel - to - ERelectrode}} .$$

$$Equation 6$$

$${V}_{ERtop} = {V}_{ERmidlevel} = \frac{{C}_{ERmidlevel - to - ERelectrode}}{{C}_{ERtop - to - ERmidlevel}} ( {V}_{ERmidlevel} - {V}_{ERelectrode} ) .$$

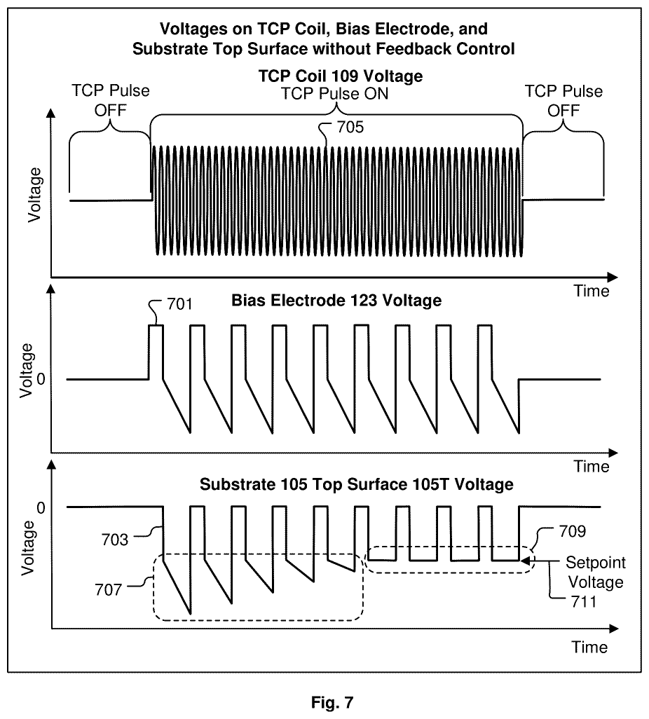

FIG. 7 shows an example of a bias voltage tailored waveform 701 supplied to the bias electrode 123 by the bias voltage supply system 333, and a corresponding voltage waveform 703 generated on the top surface 105T of the substrate 105, in accordance with some embodiments. FIG. 7 also shows a TCP voltage waveform 705 that represents the voltage on the coil 109 resulting from supply of TCP RF power to the coil 109 by the TCP RF generator 113. In the example of FIG. 7, RF power is supplied to the TCP coil 109 in a pulsed manner, such that successive ON pulses of TCP RF power are separated by an OFF pulse of the TCP RF power. The duty cycle of the ON and OFF pulses of the TCP RF power, i.e., the duration of the ON pulse relative to the duration of the OFF, is prescribed in a plasma processing recipe. Supply of the bias voltage tailored waveform 701 to the bias electrode 123 is synchronized to coincide with each ON pulse of the TCP RF power supplied to the TCP coil 109.

With single-level TCP RF power pulsing, such as shown in FIG. 7, the plasma 119 experiences a dynamic change over each pulsing state, such as a change in density. Therefore, even though the bias voltage tailored waveform 701 that is supplied to the bias electrode 123 has a consistent pulse pattern that should generate a consistent pulse pattern in the voltage waveform 703 on the top surface 105T of the substrate 105 over the duration of the ON pulse of the TCP RF power, dynamic changes in the plasma 119 cause the voltage waveform 703 on the top surface 105T of the substrate 105 to have an initial settling time when the bias voltage tailored waveform 701 is supplied to the bias electrode 123, as indicated by the region 707. Specifically, when the bias voltage tailored waveform 701 is first supplied to the bias electrode 123 at the start of the ON pulse of the TCP RF power in order to generate the voltage waveform 703 on the top surface 105T of the substrate 105, the plasma 119 density is relatively low and the ion flux incident on the substrate 105 is correspondingly low. Therefore, at the beginning of the ON pulse of the TCP RF power, the incident flux of ions on the substrate 105 does not yet electrically neutralize enough of the negative voltage on the top surface 105T of the substrate 105 to achieve a constant setpoint voltage 711 of the top surface 105T of the substrate 105. As the ON pulse of the TCP RF power proceeds, the plasma 119 density increases to reach a steady-state and the ion flux incident on the substrate 105 correspondingly increases to reach a steady-state, thereby electrically neutralizing more of the negative voltage on the top surface 105T of the substrate 105, until the constant setpoint voltage 711 in achieved on the top surface 105T of the substrate 105, as indicated by the region 709 of the voltage waveform 703.

It is of interest to control the bias voltage tailored waveform 701 supplied to the bias electrode 123 so as to generate the voltage waveform 703 on the top surface 105T of the substrate 105 in a manner that minimizes the initial settling time of the voltage waveform 103, as indicated by the region 707. In other words, it is of interest to control the bias voltage tailored waveform 701 supplied to the bias electrode 123 so that the constant setpoint voltage 711 on the top surface 105T of the substrate 105 is achieved and maintained as the plasma 119 density increases to its steady-state condition during the ON pulse of the TCP RF power. In order to control the bias voltage tailored waveform 701 supplied to the bias electrode 123 in the aforementioned manner, it is necessary to have a real-time determination of the voltage on the top surface 105T of the substrate 105 as a feedback control signal to the bias voltage supply system 333. The technique described above with regard to Equations 1 through 3 is used to determine the real-time substrate 105 top surface 105T voltage (V_{substrate}) through direct measurement of the real-time bias electrode 123 voltage (V_{biaselectrode}) and direct measurement of the real-time mid-level electrode 302 voltage (V_{midlevel}). The determined real-time substrate 105 top surface 105T voltage (V_{substrate}) is used as a closed-loop feedback control signal for controlling generation of the bias voltage tailored waveform 701, so as to generate the voltage waveform 703 on the top surface 105T of the substrate 105 in a manner that minimizes the initial settling time of the voltage waveform 103 in order to achieve and maintain the constant setpoint voltage 711 on the top surface 105T of the substrate 105 as quickly as possible after the start of each ON pulse of the TCP RF power.

In some embodiments, the real-time substrate 105 top surface 105T voltage (V_{substrate}) is provided to the bias voltage supply system 333, by way of the controller 351, for use in determining an adjustment of the prescribed bias voltage tailored waveform 342 that is to be implemented in a next pulse of the prescribed bias voltage tailored waveform 342. It should be understood that essentially any aspect of the prescribed bias voltage tailored waveform 342 can be adjusted as needed to minimize a difference between the feedback signal, i.e., the real-time substrate 105 top surface 105T voltage (V_{substrate}), and the constant setpoint voltage 711. For example, parameters of the prescribed bias voltage tailored waveform 342 such as the initial negative voltage (Vstep), the negative voltage slope (dV/dT), and the duty cycle (duration of negative voltage within a given pulse) can be controlled to minimize the difference between the determined real-time substrate 105 top surface 105T voltage (V_{substrate}) and the constant setpoint voltage 711.

It should be understood that the closed-loop feedback control method for the voltage generated on the top surface 105T of the substrate 105 as described with regard to FIG. 7 is equally applicable to controlling the voltage generated on the top surface 315T of the edge ring 315. Specifically, the technique described above with regard to Equations 4 through 6 is used to determine the real-time edge ring 315 top surface 315T voltage (V_{ERtop}) through direct measurement of the real-time edge ring electrode 323 voltage (V_{ERelectrode}) and direct measurement of the real-time edge ring mid-level electrode 317 voltage (V_{ERmidlevel}). The determined real-time edge ring 315 top surface 315T voltage (V_{ERtop}) is used as a closed-loop feedback control signal for controlling generation of the bias voltage tailored waveform applied to the edge ring electrode 323, so as to generate the voltage waveform on the top surface 315T of the edge ring 315 in a manner that minimizes the initial settling time of the voltage waveform in order to achieve and maintain a constant setpoint voltage on the top surface 315T of the edge ring 315 as quickly as possible after the start of each ON pulse of the TCP RF power.

In some embodiments, the real-time edge ring 315 top surface 315T voltage (V_{ERtop}) is provided to the bias voltage supply system 333, by way of the controller 351, for use in determining an adjustment of the prescribed bias voltage tailored waveform 342, 342-2 that is to be implemented in a next pulse of the prescribed bias voltage tailored waveform 342, 342-2. It should be understood that essentially any aspect of the prescribed bias voltage tailored waveform 342, 342-2 can be adjusted as needed to minimize a difference between the feedback signal, i.e., the real-time edge ring 315 top surface 315T voltage (V_{ERtop}), and the constant setpoint voltage. For example, parameters of the prescribed bias voltage tailored waveform 342, 342-2 such as the initial negative voltage (Vstep), the negative voltage slope (dV/dT), and the duty cycle (duration of negative voltage within a given pulse) can be controlled to minimize the difference between the determined real-time edge ring 315 top surface 315T voltage (V_{ERtop}) and the constant setpoint voltage.

In some embodiments, the voltage (V_{ERtop}) on the top surface 315T of the edge ring 315 is used to create a uniform plasma 119 sheath near the edge of the substrate 105 and minimize the bombarding the ion angular distribution function (IADF). In some embodiments, a smaller IADF reduces a tilting effect on the etch profile near the edge of the substrate 105, and therefore, increases the manufacturing yield. In some embodiments, the voltage (V_{ERtop}) on the top surface 315T of the edge ring 315 is compared to the voltage (V_{substrate}) on the top surface 105T of the substrate 105 to generate a feedback control signal for use in reducing a voltage differential between the top surface 105T of the substrate 105 and the top surface 315T of the edge ring 315, where the voltage differential causes an adverse increase in the IADF.

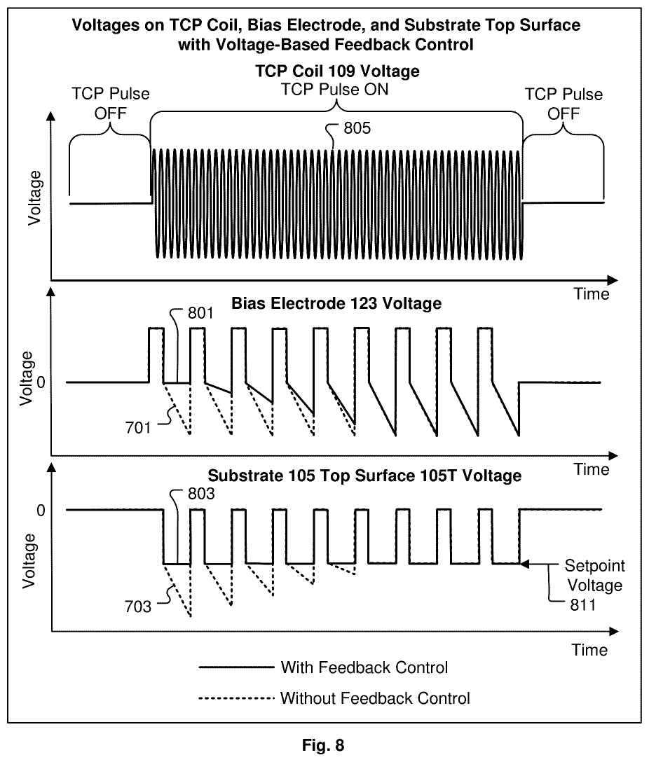

FIG. 8 shows a feedback-controlled bias voltage tailored waveform 801 supplied to the bias electrode 123 by the bias voltage supply system 333 and a corresponding voltage waveform 803 generated on the top surface 105T of the substrate 105, in accordance with some embodiments. FIG. 8 also shows a TCP voltage waveform 805 that represents the voltage on the coil 109 resulting from supply of TCP RF power to the coil 109 by the TCP RF generator 113. Also, for comparison purposes, FIG. 8 shows the non-feedback controlled bias voltage tailored waveform 701 supplied to the bias electrode 123 and the corresponding voltage waveform 703 generated on the top surface 105T of the substrate 105 from FIG. 7. FIG. 8 shows that use of the determined real-time substrate 105 top surface 105T voltage (V_{substrate}) as the feedback signal to achieve the constant setpoint voltage 811 on the top surface 105T of the substrate 105, causes the feedback-controlled bias voltage tailored waveform 801 to gradually increase in slope (dV/dT) between successive pulses of the feedback-controlled bias voltage tailored waveform 801, until the plasma 119 density reaches steady-state during the ON pulse of the TCP RF power.

It should be understood that the closed-loop feedback control method for the voltage generated on the top surface 105T of the substrate 105 as described with regard to FIG. 8 is equally applicable to controlling the voltage generated on the top surface 315T of the edge ring 315. Specifically, use of the determined real-time edge ring 315 top surface 315T voltage (V_{ERtop}) as the feedback signal to achieve a constant setpoint voltage on the top surface 315T of the edge ring 315, causes the feedback-controlled bias voltage tailored waveform supplied to the edge ring electrode 323 to gradually increase in slope (dV/dT) between successive pulses of the feedback-controlled bias voltage tailored waveform supplied the edge ring electrode 323, until the plasma 119 density reaches steady-state during the ON pulse of the TCP RF power.

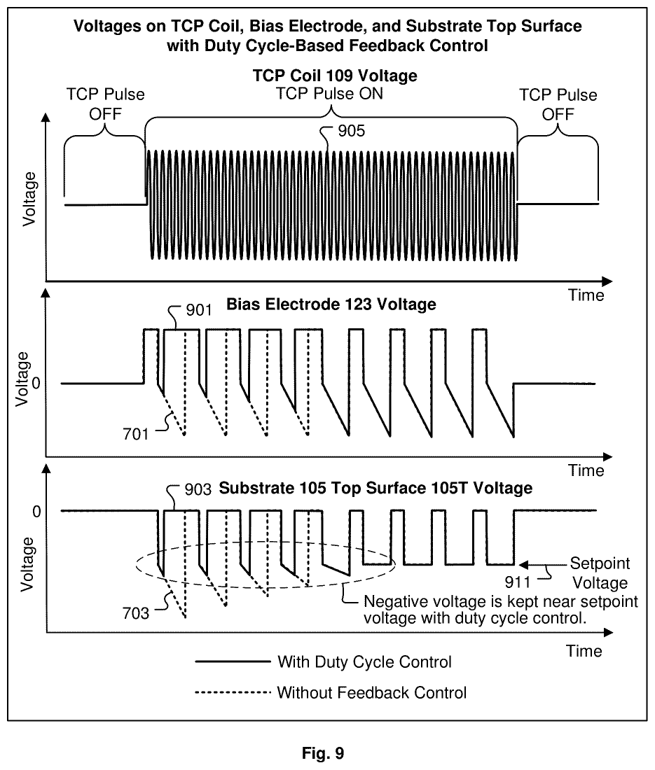

FIG. 9 shows a feedback-controlled bias voltage tailored waveform 901 supplied to the bias electrode 123 by the bias voltage supply system 333 and a corresponding voltage waveform 903 generated on the top surface 105T of the substrate 105, in accordance with some embodiments. FIG. 9 also shows a TCP voltage waveform 905 that represents the voltage on the coil 109 resulting from supply of TCP RF power to the coil 109 by the TCP RF generator 113. Also, for comparison purposes, FIG. 9 shows the non-feedback controlled bias voltage tailored waveform 701 supplied to the bias electrode 123 and the corresponding voltage waveform 703 generated on the top surface 105T of the substrate 105 from FIG. 7. FIG. 9 shows that use of the determined real-time substrate 105 top surface 105T voltage (V_{substrate}) as the feedback signal to achieve the constant setpoint voltage 911 on the top surface 105T of the substrate 105, causes the feedback-controlled bias voltage tailored waveform 801 to gradually increase in duty cycle between successive pulses of the feedback-controlled bias voltage tailored waveform 901, until the plasma 119 density reaches steady-state during the ON pulse of the TCP RF power. The duty cycle of the feedback-controlled bias voltage tailored waveform 901 is defined as the percentage of a given pulse of the feedback-controlled bias voltage tailored waveform 901 during which negative voltage is applied. The duty cycle of the feedback-controlled bias voltage tailored waveform 901 can vary from pulse-to-pulse of the feedback-controlled bias voltage tailored waveform 901. In some embodiments, such as shown in FIG. 9, the slope (dV/dT) of the feedback-controlled bias voltage tailored waveform 901 is substantially constant during the negative voltage portion of each pulse of the feedback-controlled bias voltage tailored waveform 901, regardless of the duty cycle applied during the pulse. However, in some embodiments, the slope (dV/dT) during the negative voltage portion of each pulse of the feedback-controlled bias voltage tailored waveform 901 is adjusted from pulse-to-pulse of the feedback-controlled bias voltage tailored waveform 901.

In some embodiments, the real-time substrate 105 top surface 105T voltage (V_{substrate}) is determined with a high enough sampling/measurement rate that it is possible to detect in real-time when a difference between the real-time substrate 105 top surface 105T voltage (V_{substrate}) and the setpoint voltage 911 exceeds a prescribed threshold value. In these embodiments, whenever the difference between the real-time substrate 105 top surface 105T voltage (V_{substrate}) and the setpoint voltage 911 exceeds the prescribed threshold value, the negative voltage portion of the current pulse of the feedback-controlled bias voltage tailored waveform 901 is automatically ended, which corresponds to automatic closed-loop feedback-control of the duty cycle of the bias voltage tailored waveform 901.

In some embodiments, controlling the duty cycle of the bias voltage tailored waveform 901 provides for limiting of the bias voltage tailored waveform 901 within a range extending between an upper voltage boundary and a lower voltage boundary. Also, in some embodiments, controlling the duty cycle of the bias voltage tailored waveform 901 provides for protection from voltage surge in accordance with a control algorithm. Additionally, controlling the duty cycle of the bias voltage tailored waveform 901 provides for immediate impact on the ion energy in-situ. In various embodiments, any one or more parameters of the bias voltage tailored waveform 901 can be feedback-controlled to minimize a difference between the determined real-time substrate 105 top surface 105T voltage (V_{substrate}) and the constant setpoint voltage 911 that is to be achieved and maintained on the top surface 105T of the substrate 105. For example, in some embodiments, one or more of the positive period of the bias voltage tailored waveform 901, the negative period of the bias voltage tailored waveform 901, and the frequency of the bias voltage tailored waveform 901 is feedback-controlled using the determined real-time substrate 105 top surface 105T voltage (V_{substrate}) as the feedback control signal in order to achieve and maintain the constant setpoint voltage 911 on the top surface 105T of the substrate 105.

It should be understood that the closed-loop feedback control method for the voltage generated on the top surface 105T of the substrate 105 as described with regard to FIG. 9 is equally applicable to controlling the voltage generated on the top surface 315T of the edge ring 315, particularly when the bias voltage supply system 333B of FIG. 3G is implemented. Specifically, use of the determined real-time edge ring 315 top surface 315T voltage (V_{ERtop}) as the feedback signal to achieve the constant setpoint voltage on the top surface 315T of the edge ring 315, causes the feedback-controlled bias voltage tailored waveform that is supplied to the edge ring electrode 323 to gradually increase in duty cycle between successive pulses of the feedback-controlled bias voltage tailored waveform that is supplied to the edge ring electrode 323, until the plasma 119 density reaches steady-state during the ON pulse of the TCP RF power.

Maintaining a small IADF while pulsing of the TCP RF power can be challenging due to the capacitance difference between the substrate support 301 and the edge ring 315. Because the edge ring 315 typically has smaller a surface area than the substrate support 301, the edge ring 315 has a smaller capacitance than the substrate support 301. The smaller capacitance of the edge ring 315 results in larger voltage variation on the top surface 315T of the edge ring 315. Feedback control of voltage amplitude typically requires more time to regulate for a larger deviation from target voltage. Therefore, because the edge ring 315 has smaller capacitance than the substrate support 301, faster feedback control is required for the edge ring 315 than for the substrate support 301. When either the substrate 105 top surface 105T voltage or the edge ring 315 top surface 315T voltage goes out of feedback control, there can be large voltage difference between the top surface 105T of the substrate 105 and the top surface 315T of the edge ring 315, which can cause a large IADF and corresponding adverse etch tilting. In some embodiments, when the bias voltage supply system 333A of FIG. 3D is implemented, closed-loop feedback control of the duty cycle of the bias voltage tailored waveform 342 provides for limiting of the voltage differential between the top surface 105T of the substrate 105 and the top surface 315T of the edge ring 315, so as to maintain a small IADF near the edge of the substrate 105. In some embodiments, when the bias voltage supply system 333B of FIG. 3G is implemented, independent closed-loop feedback control of each of the bias voltage tailored waveforms 342-1 and 342-2 provides for limiting of the voltage differential between the top surface 105T of the substrate 105 and the top surface 315T of the edge ring 315, so as to maintain a small IADF near the edge of the substrate 105.

In some embodiments, the bias voltage supply system 333 includes the bias electrode 123 disposed within the substrate support 301 and the mid-level electrode 302 disposed within the substrate support 301, such that the lower portion 303 of the substrate support 301 is present between the bias electrode 123 and the mid-level electrode 302, and such that the upper portion 305 of the substrate support 301 is present between the mid-level electrode 302 and the top surface 301T of the substrate support 301. The bias voltage supply system 333 also includes the voltage supply system 341, 391 connected to supply a bias voltage tailored radiofrequency waveform to the bias electrode 123. In some embodiments, the bias voltage tailored radiofrequency waveform is defined as an ongoing series of pulse cycles, where each pulse cycle includes an on-duration in which the bias voltage tailored radiofrequency waveform has a negative voltage and an off-duration in which the bias voltage tailored radiofrequency waveform has a positive voltage. The bias voltage supply system 333 also includes a voltage measurement system connected to measure a first voltage on the bias electrode 123 and a second voltage on the mid-level electrode 302. The bias voltage supply system 333 also includes the controller 351 (or portion thereof) configured to use the measured first voltage, the measured second voltage, a capacitance of the lower portion 303 of the substrate support 301, and a capacitance of the upper portion 305 of the substrate support 301 to determine the voltage on the top surface 105T of the substrate 105 present on the top surface 301T of the substrate support 301. The controller 315 is configured to convey the voltage on the top surface 105T of the substrate 105 to the voltage supply system 341, 391.

In some embodiments, the voltage supply system 341, 391 is configured to adjust the bias voltage tailored radiofrequency waveform to minimize a difference between a setpoint voltage and the voltage on the top surface 105T of the substrate 105. In some embodiments, the voltage supply system 341, 391 is configured to adjust the bias voltage tailored radiofrequency waveform within one pulse cycle of the bias voltage tailored radiofrequency waveform. In some embodiments, the controller 351 is configured to determine the voltage on the top surface 105T of the substrate 105 by computing a sum of a first term and a second term, wherein the first term is equal to the second voltage on the mid-level electrode 302, wherein the second term is equal to a product of a constant and a differential voltage, wherein the constant is equal to a ratio of the capacitance of the lower portion 303 of the substrate support 301 over the capacitance of the upper portion 305 of the substrate support 301, and wherein the differential voltage is equal to the second voltage on the mid-level electrode 302 minus the first voltage on the bias electrode 123.

In some embodiments, the bias voltage supply system 333 also includes the edge ring electrode 323 disposed within the edge ring 315 that is configured to circumscribe the substrate support 301. The edge ring electrode 323 is configured to control the voltage on the top surface 315T of the edge ring 315. The bias voltage tailored radiofrequency waveform supplied to the bias electrode 123 within the substrate support 301 is a first bias voltage tailored radiofrequency waveform. The edge ring electrode 323 is connected to receive a second bias voltage tailored radiofrequency waveform from the voltage supply system 341, 396. In some embodiments, the second bias voltage tailored radiofrequency waveform is defined as an ongoing series of pulse cycles, where each pulse cycle includes an on-duration in which the second bias voltage tailored radiofrequency waveform has a negative voltage and an off-duration in which the second bias voltage tailored radiofrequency waveform has a positive voltage. The bias voltage supply system 333 also includes the edge ring mid-level electrode 317 disposed within the edge ring 315, such that a lower portion 319 of the edge ring 315 is present between the edge ring electrode 323 and the edge ring mid-level electrode 317, and such that an upper portion 321 of the edge ring 315 is present between the edge ring mid-level electrode 317 and the top surface 315T of the edge ring 315.

The voltage measurement system is connected to measure a third voltage on the edge ring electrode 323 and a fourth voltage on the edge ring mid-level electrode 317. The controller 315 is configured to use the measured third voltage on the edge ring electrode 323, the measured fourth voltage on the edge ring mid-level electrode 317, a capacitance of the lower portion 319 of the edge ring 315, and a capacitance of the upper portion 321 of the edge ring 315 to determine the voltage on the top surface 315T of the edge ring 315. In some embodiments, the controller 351 is configured to determine the voltage on the top surface 315T of the edge ring 315 by computing a sum of a first term and a second term, where the first term is equal to the fourth voltage on the edge ring mid-level electrode 317, where the second term is equal to a product of a constant and a differential voltage, where the constant is equal to a ratio of the capacitance of the lower portion 319 of the edge ring 315 over the capacitance of the upper portion 321 of the edge ring 315, and where the differential voltage is equal to the fourth voltage on the edge ring mid-level electrode 317 minus the third voltage on the edge ring electrode 323. The controller 315 is configured to convey the voltage on the top surface 315T of the edge ring 315 to the voltage supply system.

In some embodiments, the bias voltage supply system 333 includes a variable capacitor 359, 361, 363, 365 disposed to separately control the second bias voltage tailored radiofrequency waveform supplied to the edge ring electrode 323 relative to the first bias voltage tailored radiofrequency waveform supplied to the bias electrode 123. In some embodiments, the voltage supply system 341, 396 is configured to adjust the second bias voltage tailored radiofrequency waveform supplied to the edge ring electrode 323 to minimize a difference between a setpoint voltage and the voltage on the top surface 315T of the edge ring 315. In some embodiments, the voltage supply system 341, 396 is configured to adjust the second bias voltage tailored radiofrequency waveform supplied to the edge ring electrode 323 within one pulse cycle of the second bias voltage tailored radiofrequency waveform.

In some embodiments, a substrate support system is disclosed for the plasma processing system 300. The substrate support system includes the substrate support 301 that has the top surface 301T configured to support the substrate 105. The substrate support system includes the bias electrode 123 disposed within the substrate support 301. The bias electrode 123 is configured to control the voltage on the top surface 105T of the substrate 105. The bias electrode 123 is connected to receive a bias voltage tailored radiofrequency waveform from the voltage supply system 341, 391. The substrate support system also includes the mid-level electrode 302 disposed within the substrate support 301, such that the lower portion 303 of the substrate support 301 is present between the bias electrode 123 and the mid-level electrode 302, and such that the upper portion 305 of the substrate support 301 is present between the mid-level electrode 302 and the top surface 301T of the substrate support 301. The substrate support system also includes a first connector 313 electrically connected to the bias electrode 123 for measuring a first real-time voltage on the bias electrode 123. The bias electrode 123 is configured to electrically receive the first connector 313 for measuring the first real-time voltage on the bias electrode 123. The substrate support system also includes a second connector 309 electrically connected to the mid-level electrode 302 for measuring a second real-time voltage on the mid-level electrode 302. The mid-level electrode 302 is configured to electrically receive the second connector 309 for measuring the second real-time voltage on the mid-level electrode 302. The substrate support system also includes the controller 315 configured to use the measured first real-time voltage on the bias electrode 123, the measured second real-time voltage on the mid-level electrode 302, a capacitance of the lower portion 303 of the substrate support 301, and a capacitance of the upper portion 305 of the substrate support 301 to determine the real-time voltage on the top surface 105T of the substrate 105.

In some embodiments, an edge ring system is disclosed for the plasma processing system 300. The edge ring system includes the edge ring 315 configured to circumscribe the substrate support 301. The edge ring system also includes an edge ring electrode 323 disposed within the edge ring 315. The edge ring electrode 323 is configured to control the voltage on the top surface 315T of the edge ring 315. The edge ring electrode 323 is connected to receive a bias voltage tailored radiofrequency waveform from the voltage supply system 341, 396. The edge ring system also includes the edge ring mid-level electrode 317 disposed within the edge ring 315, such that the lower portion 319 of the edge ring 315 is present between the edge ring electrode 323 and the edge ring mid-level electrode 317, and such that the upper portion 321 of the edge ring 315 is present between the edge ring mid-level electrode 317 and the top surface 315T of the edge ring 315. The edge ring system also includes a first connector 327 electrically connected to the edge ring electrode 323 for measuring a first real-time voltage on the edge ring electrode 323. The edge ring electrode 323 is configured to electrically receive the first connector 327 for measuring the first real-time voltage on the edge ring electrode 323. The edge ring system also includes a second connector 331 electrically connected to the edge ring mid-level electrode 317 for measuring a second real-time voltage on the edge ring mid-level electrode 317. The edge ring mid-level electrode 317 is configured to electrically receive the second connector 331 for measuring the second real-time voltage on the edge ring mid-level electrode 317. The controller 315 is configured to use the measured first real-time voltage on the edge ring electrode 323, the measured second real-time voltage on the edge ring mid-level electrode 317, a capacitance of the lower portion 319 of the edge ring 315, and a capacitance of the upper portion 321 of the edge ring 315 to determine the real-time voltage on the top surface 315T of the edge ring 315.

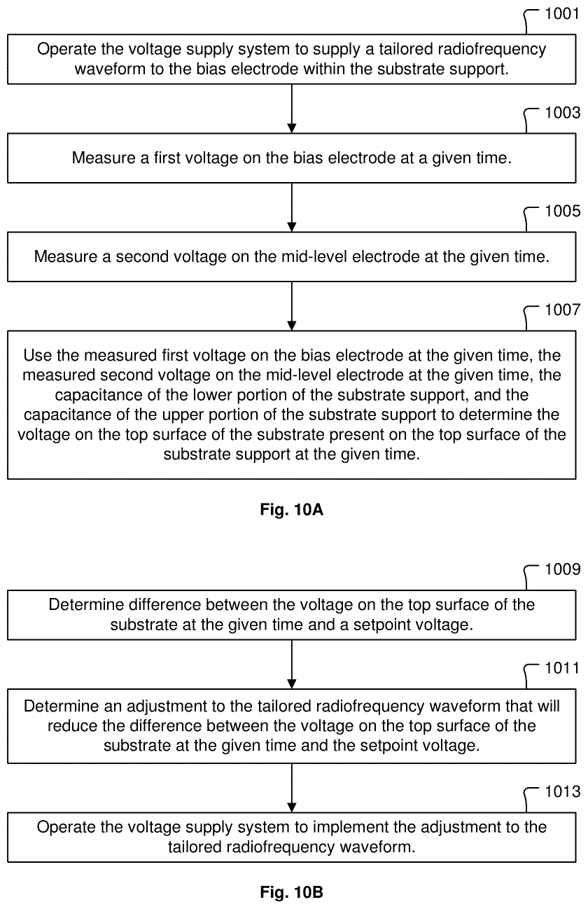

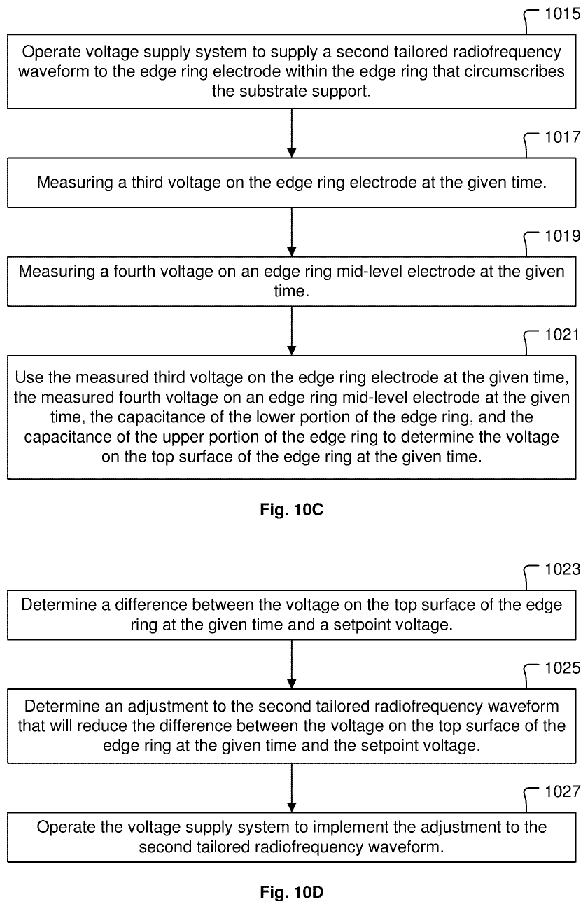

FIG. 10A shows a flowchart of a method for controlling voltage on the substrate 105, in accordance with some embodiments. The method includes an operation 1001 for operating the voltage supply system 341, 391 to supply a bias voltage tailored radiofrequency waveform to the bias electrode 123 within the substrate support 301. The method also includes an operation 1003 for measuring a first voltage on the bias electrode 123 at a given time. It should be understood that various electrical parameters, such as voltage, can be determined/calculated using other related parameters, e.g., V=IR, where V is voltage, I is current, and R is resistance. Therefore, it should be understood that the various voltage measurements mentioned herein can be made by either a direct voltage measurement or an indirect voltage measurement, where the indirect voltage measurement includes determination/measurement of one or more parameters related to the voltage to be measured and subsequent determination/calculation of the voltage to be measured using the one or more parameters related to the voltage to be measured. The method also includes an operation 1005 for measuring a second voltage on the mid-level electrode 302 at the given time. The method also includes an operation 1007 for using the measured first voltage on the bias electrode 123 at the given time, the measured second voltage on the mid-level electrode 302 at the given time, the capacitance of the lower portion 303 of the substrate support 301, and the capacitance of the upper portion 305 of the substrate support 301 to determine the voltage on the top surface 105T of the substrate 105 present on the top surface 301T of the substrate support 301 at the given time.

FIG. 10B shows a flowchart of an optional continuation of the method of FIG. 10A for controlling voltage on the substrate 105, in accordance with some embodiments. The method includes an operation 1009 for determining a difference between the voltage on the top surface 105T of the substrate 105 at the given time and a setpoint voltage. The method also includes an operation 1011 for determining an adjustment to the bias voltage tailored radiofrequency waveform that will reduce the difference between the voltage on the top surface 105T of the substrate 105 at the given time and the setpoint voltage. The method also includes an operation 1013 for operating the voltage supply system 341, 391 to implement the adjustment to the bias voltage tailored radiofrequency waveform.

In some embodiments, the given time occurs during a negative portion of a cycle of the bias voltage tailored radiofrequency waveform, and operation 1013 is performed to implement the adjustment to the bias voltage tailored radiofrequency waveform during a negative portion of a next cycle of the bias voltage tailored radiofrequency waveform. In some embodiments, the adjustment to the bias voltage tailored radiofrequency waveform is a change in voltage as a function of time during the negative portion of the next cycle of the bias voltage tailored radiofrequency waveform. In some embodiments, the adjustment to the bias voltage tailored radiofrequency waveform is a change in a duration of the negative portion of the next cycle of the bias voltage tailored radiofrequency waveform.

FIG. 10C shows a flowchart of an optional continuation of the method of either FIG. 10A or FIG. 10B, in accordance with some embodiments. The method includes an operation 1015 for operating the voltage supply system 341, 396 to supply a second bias voltage tailored radiofrequency waveform to the edge ring electrode 323 within the edge ring 315 that circumscribes the substrate support 301. In this embodiment, the bias voltage tailored radiofrequency waveform supplied to the bias electrode 123 within the substrate support 301 is referred to as a first bias voltage tailored radiofrequency waveform. The method also includes an operation 1017 for measuring a third voltage on the edge ring electrode 323 at the given time. The method also includes an operation 1019 for measuring a fourth voltage on an edge ring mid-level electrode 317 at the given time. The method also includes an operation 1021 for using the measured third voltage on the edge ring electrode 323 at the given time, the measured fourth voltage on an edge ring mid-level electrode 317 at the given time, the capacitance of the lower portion 319 of the edge ring 315, and the capacitance of the upper portion 321 of the edge ring 315 to determine the voltage on the top surface 315T of the edge ring 315 at the given time.

FIG. 10D shows a flowchart of an optional continuation of the method of FIG. 10C for controlling voltage on the edge ring 315, in accordance with some embodiments. The method includes an operation 1023 for determining a difference between the voltage on the top surface 315T of the edge ring 315 at the given time and a setpoint voltage. The method also includes an operation 1025 for determining an adjustment to the second bias voltage tailored radiofrequency waveform that will reduce the difference between the voltage on the top surface 315T of the edge ring 315 at the given time and the setpoint voltage. The method also includes an operation 1027 for operating the voltage supply system 341, 396 to implement the adjustment to the second bias voltage tailored radiofrequency waveform. In some embodiments, the given time occurs during a negative portion of a cycle of the second bias voltage tailored radiofrequency waveform, and operation 1027 is performed to implement the adjustment to the second bias voltage tailored radiofrequency waveform during a negative portion of a next cycle of the second bias voltage tailored radiofrequency waveform. In some embodiments, the adjustment to the second bias voltage tailored radiofrequency waveform is a change in voltage as a function of time during the negative portion of the next cycle of the second bias voltage tailored radiofrequency waveform. In some embodiments, the adjustment to the second bias voltage tailored radiofrequency waveform is a change in a duration of the negative portion of the next cycle of the second bias voltage tailored radiofrequency waveform.

The various embodiments described herein may be practiced in conjunction with various computer system configurations including hand-held hardware units, microprocessor systems, microprocessor-based or programmable consumer electronics, minicomputers, mainframe computers and the like. The various embodiments described herein can also be practiced in conjunction with distributed computing environments where tasks are performed by remote processing hardware units that are linked through a computer network. It should also be understood that the various embodiments disclosed herein include performance of various computer-implemented operations involving data stored in computer systems. These computer-implemented operations are those that manipulate physical quantities. In various embodiments, the computer-implemented operations are performed by either a general purpose computer or a special purpose computer. In some embodiments, the computer-implemented operations are performed by a selectively activated computer, and/or are directed by one or more computer programs stored in a computer memory or obtained over a computer network. When computer programs and/or digital data is obtained over the computer network, the digital data may be processed by other computers on the computer network, e.g., a cloud of computing resources. The computer programs and digital data are stored as computer-readable code on a non-transitory computer-readable medium. The non-transitory computer-readable medium is any data storage hardware unit, e.g., a memory device, etc., that stores data, which is thereafter readable by a computer system. Examples of the non-transitory computer-readable medium include hard drives, network attached storage (NAS), ROM, RAM, compact disc-ROMs (CD-ROMs), CD-recordables (CD-Rs), CD-rewritables (CD-RWs), digital video/versatile disc (DVD), magnetic tapes, and other optical and non-optical data storage hardware units. In some embodiments, the computer programs and/or digital data are distributed among multiple computer-readable media located in different computer systems within a network of coupled computer systems, such that the computer programs and/or digital data is executed and/or stored in a distributed fashion.

Although the foregoing disclosure includes some detail for purposes of clarity of understanding, it will be apparent that certain changes and modifications can be practiced within the scope of the appended claims. For example, it should be understood that one or more features from any embodiment disclosed herein may be combined with one or more features of any other embodiment disclosed herein. Accordingly, the present embodiments are to be considered as illustrative and not restrictive, and what is claimed is not to be limited to the details given herein, but may be modified within the scope and equivalents of the described embodiments.

What is claimed is:

1. A system, comprising:
a bias electrode disposed within a substrate support, the substrate support having a top surface configured to support a substrate;
a mid-level electrode disposed within the substrate support such that a lower portion of the substrate support is present between the bias electrode and the mid-level electrode and such that an upper portion of the substrate support is present between the mid-level electrode and the top surface of the substrate support;
a voltage supply system connected to supply a bias voltage tailored radiofrequency waveform to the bias electrode;
a voltage measurement system connected to measure a first voltage on the bias electrode and a second voltage on the mid-level electrode; and
a controller configured to use the measured first voltage, the measured second voltage, a capacitance of the lower portion of the substrate support, and a capacitance of the upper portion of the substrate support to determine a voltage on a top surface of the substrate when present on the top surface of the substrate support, the controller configured to convey information related to the voltage on the top surface of the substrate to the voltage supply system.

2. The system as recited in claim 1, wherein the bias voltage tailored radiofrequency waveform is defined as an ongoing series of pulse cycles, wherein each pulse cycle includes an on-duration in which the bias voltage tailored radiofrequency waveform has a negative voltage and an off-duration in which the bias voltage tailored radiofrequency waveform has a positive voltage.

3. The system as recited in claim 2, wherein the voltage supply system is configured to adjust the bias voltage tailored radiofrequency waveform to minimize a difference between a setpoint voltage and the voltage on the top surface of the substrate.

4. The system as recited in claim 3, wherein the voltage supply system is configured to adjust the bias voltage tailored radiofrequency waveform within one pulse cycle of the bias voltage tailored radiofrequency waveform.

5. The system as recited in claim 1, wherein the controller is configured to determine the voltage on the top surface of the substrate by computing a sum of a first term and a second term, wherein the first term is equal to the second voltage, wherein the second term is equal to a product of a constant and a differential voltage, wherein the constant is equal to a ratio of the capacitance of the lower portion of the substrate support over the capacitance of the upper portion of the substrate support, and wherein the differential voltage is equal to the second voltage minus the first voltage.

6. The system as recited in claim 1, further comprising:
an edge ring electrode disposed within an edge ring configured to circumscribe the substrate support, the edge ring electrode configured to control a voltage on a top surface of the edge ring, wherein the bias voltage tailored radiofrequency waveform supplied to the bias electrode within the substrate support is a first bias voltage tailored radiofrequency waveform, the edge ring electrode connected to receive a second bias voltage tailored radiofrequency waveform from the voltage supply system; and
an edge ring mid-level electrode disposed within the edge ring such that a lower portion of the edge ring is present between the edge ring electrode and the edge ring mid-level electrode and such that an upper portion of the edge ring is present between the edge ring mid-level electrode and the top surface of the edge ring, wherein the voltage measurement system is connected to measure a third voltage on the edge ring electrode and a fourth voltage on the edge ring mid-level electrode,
wherein the controller is configured to use the measured third voltage, the measured fourth voltage, a capacitance of the lower portion of the edge ring, and a capacitance of the upper portion of the edge ring to determine a voltage on the top surface of the edge ring, the controller configured to convey information related to the voltage on the top surface of the edge ring to the voltage supply system.

7. The system as recited in claim 6, further comprising:
a variable capacitor disposed to separately control the second bias voltage tailored radiofrequency waveform relative to the first bias voltage tailored radiofrequency waveform.

8. The system as recited in claim 6, wherein the second bias voltage tailored radiofrequency waveform is defined as an ongoing series of pulse cycles, wherein each pulse cycle includes an on-duration in which the second bias voltage tailored radiofrequency waveform has a negative voltage and an off-duration in which the second bias voltage tailored radiofrequency waveform has a positive voltage.

9. The system as recited in claim 8, wherein the voltage supply system is configured to adjust the second bias voltage tailored radiofrequency waveform to minimize a difference between a setpoint voltage and the voltage on the top surface of the edge ring.

10. The system as recited in claim 9, wherein the voltage supply system is configured to adjust the second bias voltage tailored radiofrequency waveform within one pulse cycle of the second bias voltage tailored radiofrequency waveform.

11. The system as recited in claim 7, wherein the controller is configured to determine the voltage on the top surface of the edge ring by computing a sum of a first term and a second term, wherein the first term is equal to the fourth voltage, wherein the second term is equal to a product of a constant and a differential voltage, wherein the constant is equal to a ratio of the capacitance of the lower portion of the edge ring over the capacitance of the upper portion of the edge ring, and wherein the differential voltage is equal to the fourth voltage minus the third voltage.

12. A substrate support system for a plasma processing system, comprising:
a substrate support having a top surface configured to support a substrate;
a bias electrode disposed within the substrate support, the bias electrode configured to control a voltage on a top surface of the substrate, the bias electrode connected to receive a bias voltage tailored radiofrequency waveform from a voltage supply system, wherein the bias electrode is configured to electrically receive a first connector for measuring a first voltage on the bias electrode; and
a mid-level electrode disposed within the substrate support such that a lower portion of the substrate support is present between the bias electrode and the mid-level electrode and such that an upper portion of the substrate support is present between the mid-level electrode and the top surface of the substrate support, wherein the mid-level electrode is configured to electrically receive a second connector for measuring a second voltage on the mid-level electrode.

13. The substrate support system for the plasma processing system as recited in claim 12, further comprising:
a controller configured to use the measured first voltage, the measured second voltage, a capacitance of the lower portion of the substrate support, and a capacitance of the upper portion of the substrate support to determine the voltage on the top surface of the substrate.

14. An edge ring system for a plasma processing system, comprising:
an edge ring configured to circumscribe a substrate support;
an edge ring electrode disposed within the edge ring, the edge ring electrode configured to control a voltage on a top surface of the edge ring and to receive a bias voltage tailored radiofrequency waveform from a voltage supply system, wherein the edge ring electrode is configured to electrically receive a first connector for measuring a first voltage on the edge ring electrode; and
an edge ring mid-level electrode disposed within the edge ring such that a lower portion of the edge ring is present between the edge ring electrode and the edge ring mid-level electrode and such that an upper portion of the edge ring is present between the edge ring mid-level electrode and the top surface of the edge ring, wherein the edge ring mid-level electrode is configured to electrically receive a second connector for measuring a second voltage on the edge ring mid-level electrode.

15. The edge ring system for the plasma processing system as recited in claim 14, further comprising:
a controller configured to use the measured first voltage, the measured second voltage, a capacitance of the lower portion of the edge ring, and a capacitance of the upper portion of the edge ring to determine the voltage on the top surface of the edge ring.

16. A method for controlling voltage on a substrate, comprising:
operating a voltage supply system to supply a bias voltage tailored radiofrequency waveform to a bias electrode within a substrate support;
measuring a first voltage on the bias electrode at a given time;
measuring a second voltage on a mid-level electrode at the given time, the mid-level electrode disposed within the substrate support such that a lower portion of the substrate support is present between the bias electrode and the mid-level electrode and such that an upper portion of the substrate support is present between the mid-level electrode and the top surface of the substrate support; and
using the measured first voltage, the measured second voltage, a capacitance of the lower portion of the substrate support, and a capacitance of the upper portion of the substrate support to determine a voltage on a top surface of a substrate when present on a top surface of the substrate support at the given time.

17. The method as recited in claim 16, further comprising:
determining a difference between the voltage on the top surface of the substrate at the given time and a setpoint voltage;
determining an adjustment to the bias voltage tailored radiofrequency waveform that will reduce the difference between the voltage on the top surface of the substrate at the given time and the setpoint voltage; and
operating the voltage supply system to implement the adjustment to the bias voltage tailored radiofrequency waveform.

18. The method as recited in claim 17, wherein the given time occurs during a negative portion of a cycle of the bias voltage tailored radiofrequency waveform, and wherein the adjustment to the bias voltage tailored radiofrequency waveform is implemented during a negative portion of a next cycle of the bias voltage tailored radiofrequency waveform.

19. The method as recited in claim 18, wherein the adjustment to the bias voltage tailored radiofrequency waveform is a change in voltage as a function of time during the negative portion of the next cycle of the bias voltage tailored radiofrequency waveform.

20. The method as recited in claim 18, wherein the adjustment to the bias voltage tailored radiofrequency waveform is a change in a duration of the negative portion of the next cycle of the bias voltage tailored radiofrequency waveform.

21. The method as recited in claim 16, further comprising:
operating the voltage supply system to supply a second bias voltage tailored radiofrequency waveform to an edge ring electrode within an edge ring that circumscribes the substrate support, wherein the bias voltage tailored radiofrequency waveform supplied to the bias electrode within the substrate support is a first bias voltage tailored radiofrequency waveform;
measuring a third voltage on the edge ring electrode at the given time;
measuring a fourth voltage on an edge ring mid-level electrode at the given time, the edge ring mid-level electrode disposed within the edge ring such that a lower portion of the edge ring is present between the edge ring electrode and the edge ring mid-level electrode and such that an upper portion of the edge ring is present between the edge ring mid-level electrode and a top surface of the edge ring; and
using the measured third voltage, the measured fourth voltage, a capacitance of the lower portion of the edge ring, and a capacitance of the upper portion of the edge ring to determine a voltage on the top surface of the edge ring at the given time.

22. The method as recited in claim 21, further comprising:
determining a difference between the voltage on the top surface of the edge ring at the given time and a setpoint voltage;
determining an adjustment to the second bias voltage tailored radiofrequency waveform that will reduce the difference between the voltage on the top surface of the edge ring at the given time and the setpoint voltage; and
operating the voltage supply system to implement the adjustment to the second bias voltage tailored radiofrequency waveform.

23. The method as recited in claim 22, wherein the given time occurs during a negative portion of a cycle of the second bias voltage tailored radiofrequency waveform, and wherein the adjustment to the second bias voltage tailored radiofrequency waveform is implemented during a negative portion of a next cycle of the second bias voltage tailored radiofrequency waveform.

24. The method as recited in claim 23, wherein the adjustment to the second bias voltage tailored radiofrequency waveform is a change in voltage as a function of time during the negative portion of the next cycle of the second bias voltage tailored radiofrequency waveform.

25. The method as recited in claim 23, wherein the adjustment to the second bias voltage tailored radiofrequency waveform is a change in a duration of the negative portion of the next cycle of the second bias voltage tailored radiofrequency waveform.
